(19) United States
(12) Patent Application Publication
(10) Pub. No.: US 2026/0026112 A1
(43) Pub. Date: Jan. 22, 2026

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Chin-Chia KUO, Tainan City (TW); Jyh-Weei HSIA, Hsinchu County (TW); Tzu-Chieh LIN, Hsinchu (TW)

(73) Assignee: TAIWAN SEMICONDUCTOR MANUFACTURING COMPANY, LTD., Hsinchu (TW)

(21) Appl. No.: 18/779,661

(22) Filed: Jul. 22, 2024

(51) Int. Cl. H01L 27/146; H01L 23/00

(52) U.S. Cl. CPC H10F 39/028; H01L 24/08; H01L 24/80; H10F 39/018; H10F 39/199; H10F 39/809; H10F 39/811; H01L 2224/08145; H01L 2224/80895; H01L 2224/80896; H01L 2224/80908

(57) ABSTRACT

A method includes bonding a first wafer to a second wafer; after bonding the first wafer to the second wafer, bonding a third wafer to the first wafer; conducting a process control monitor on the first and second wafers via a first electrical pathway that traverses an interface between the first and second wafers; determining whether a charge present at the interface between the first and second wafers.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a stacking scheme of a stacked image sensor die (or wafer) in accordance with some embodiments of the present disclosure.

FIGS. 2-22C are schematic views of intermediate stages in the manufacturing of a stacked image sensor wafer/chip in accordance with some embodiments of the present disclosure.

FIG. 23 is a block diagram of a fabrication facility in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As Moore's law decelerates, packing more functionality into a single die may not optimally enhance power, performance, and area (PPA) for future semiconductor devices. Three-dimensional integrated circuits (3DICs) present an alternative, allowing vertical stacking of silicon wafers or dies within a single package. This method can improve across different process nodes. For instance, the production of CMOS image sensors (CIS) currently can employ a two-wafer stacking approach through wafer-on-wafer (WoW) hybrid bonding, featuring a backside Illuminated (BSI) wafer atop an image signal processor (ISP) wafer, with plans to expand to three or more layers. Challenges in the WoW process, such as alignment offsets, poor adhesive strength of the encapsulant layer (ESL), and wafer warpage, frequently contribute to high resistance failures, emphasizing the need for meticulous process monitoring. Despite the focus on bonding interface quality, unnoticed charge effects during bonding also significantly impact yield. Enhanced real-time detection methods are crucial to identify and mitigate such issues during manufacturing, ensuring the reliability and performance of 3DICs are maintained.

Therefore, the present disclosure in various embodiments provides an enhanced process control monitoring (PCM) including real-time monitoring of bonding interface charges to detect any deviations during the wafer acceptance testing (WAT). This advancement allows for immediate verification of designs using current PCM device under test (DUT) setups in any technology utilizing the WoW stacking process. By integrating PCM patterns alongside design of experiments strategies, the system can now monitor charge effects throughout the stacking process. This setup enables routine monitoring across each layer of the stack, with the DOE split helping to pinpoint interface anomalies during WAT, thus catching process irregularities before wafer final out. Specifically, WAT test patterns can utilize a gate oxide integrity (GOI) PCM framework with varied metal routing configurations to track charging behaviors specifically from WoW bonding and backside through silicon via (BTSV) processes. This method not only identifies where the charging originates during the hybrid bonding (HB) steps but also allows adjustments to the spatial pattern array (SPA) of capacitors, facilitating monitoring of charge interactions between floating and grounded states, enhancing the detection and isolation of potential issues early in the manufacturing cycle.

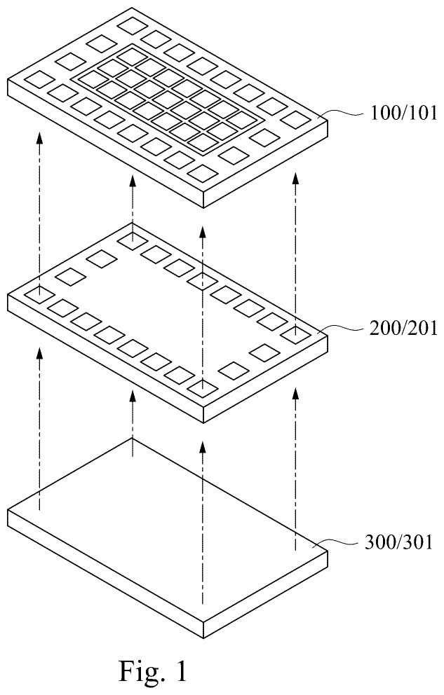

Reference is made to FIG. 1. FIG. 1 illustrates a stacking scheme of a stacked image sensor die (or wafer) in accordance with some exemplary embodiments. A wafer 100 including a backside illumination (BSI) image sensor chip 101 can be bonded to a wafer 200 including a read-out chip 201, for example, through metal-to-metal bonding or a hybrid bonding including both the metal-to-metal bonding and the oxide-to-oxide bonding. The wafer 200 can be further bonded to a wafer 300 including a peripheral circuit chip 301, which may be an application specific integrated circuit (ASIC) chip. The peripheral circuit chip 301 may include image signal processing (ISP) circuits, and may, or may not, further include other circuits that are related to the BSI applications. In other words, the bonding of the chips 101, 201, and 301 may be at wafer level. In the wafer-level bonding, the wafers 100, 200 and 300, which include the chips 101, 201, and 301, respectively, are bonded together, and are then sawed into dies. Alternatively, the bonding may be performed at the chip level.

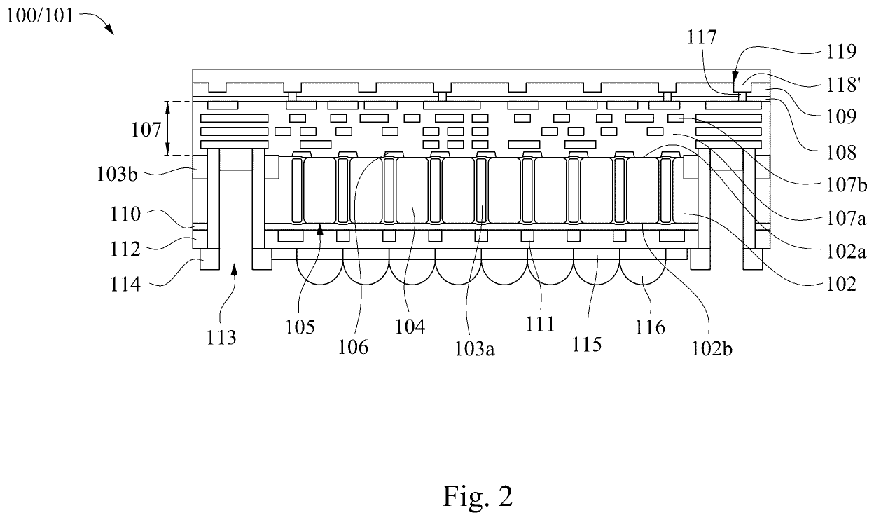

Reference is made to FIGS. 2-22C. FIGS. 2-22C are schematic views of intermediate stages in the manufacturing of a stacked image sensor wafer/chip in accordance with some embodiments of the present disclosure. It is understood that additional operations can be provided before, during, and after the processes shown by FIGS. 2-22C, and some of the operations described below can be replaced or eliminated, for additional embodiments of the method. The order of the operations/processes may be interchangeable.

Reference is made to FIG. 2. FIG. 2 illustrates the formation of an initial structure of image sensor chip 101, which may be a part of wafer 100 that includes a plurality of image sensor chips 101 therein. The image sensor chip 101 includes semiconductor substrate 102. In accordance with some embodiments of the present disclosure, semiconductor substrate 102 is a crystalline silicon substrate. In accordance with other embodiments of the present disclosure, the semiconductor substrate 102 can include an elementary semiconductor such as germanium; a compound semiconductor including silicon carbon, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates such as multi-layered or gradient substrates may also be used. Throughout the description, a surface 102a of the semiconductor substrate 102 cab be referred to as a front-side surface of semiconductor substrate 102, and a surface 102b can be referred to as a back-side surface of semiconductor substrate 102. In some embodiments, a backside grinding process can be performed to grind the surface 102b to thin semiconductor substrate 102, so that light can penetrate from back surface 102b into semiconductor substrate 102 and reach the image sensors 104.

Isolation regions 103a and 103b can be formed to extend into semiconductor substrate 102 to define regions (such as active regions). The isolation region 103a can be a grid for forming an image sensor array therein, and the isolation regions 103b can be a landing pad for forming a metal pad. In some embodiments, the isolation region 103a can include is a high-k dielectric layer, which may be made of or comprise aluminum oxide (Al2O3), hafnium oxide (HfO2), tantalum oxide (Ta2O5) or the like. In some embodiments, the isolation regions 103a can be also interchangeable referred to as deep trench isolation (DTI) regions. In some embodiments, the isolation regions 103b may be a pad that is large enough to accommodate a metal pad. In accordance with some embodiments of the present disclosure, the formation of the isolation regions 103a and 103b can include etching semiconductor substrate 102, and filling the resulting trenches with a dielectric material.

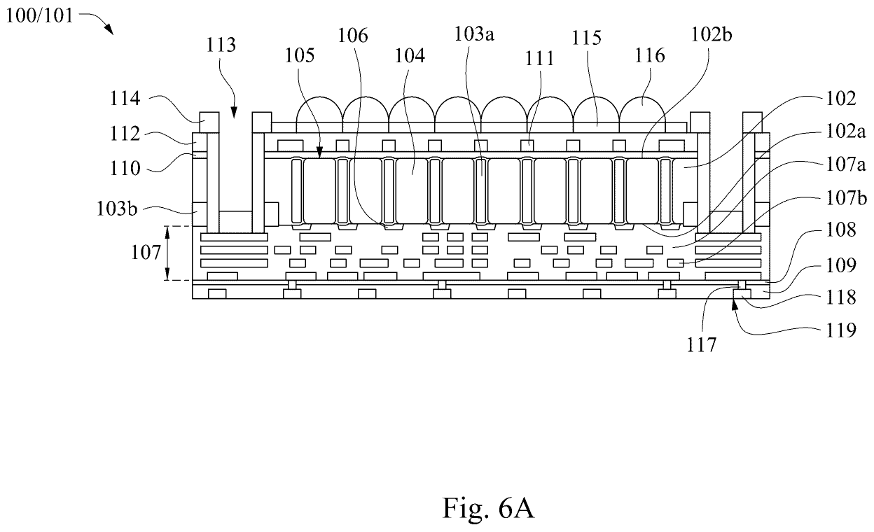

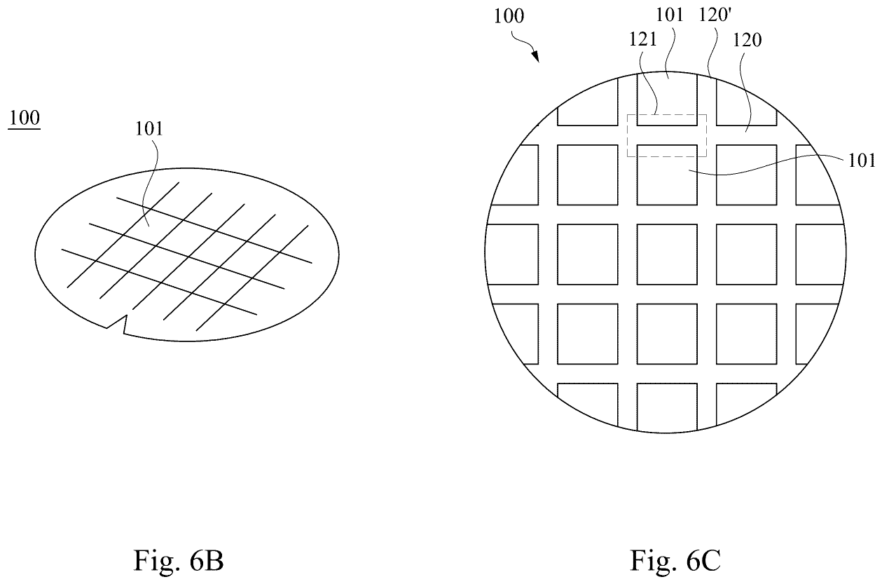

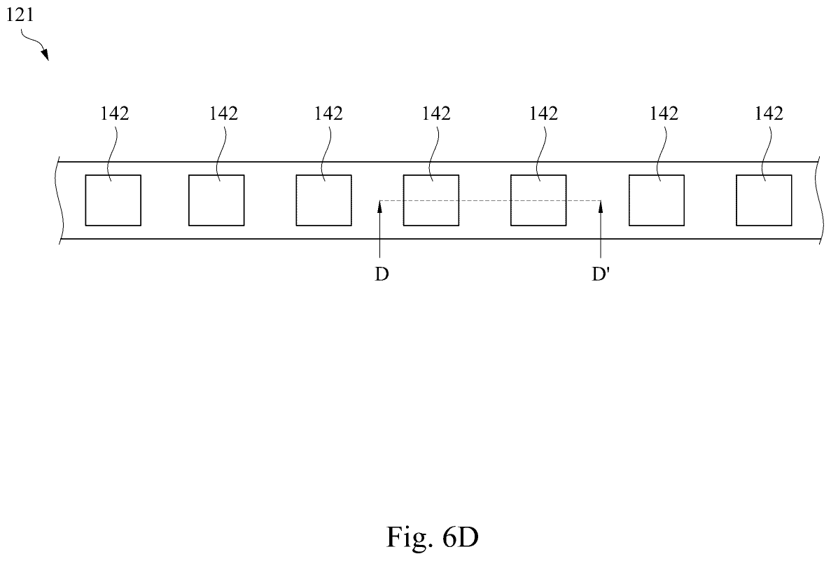

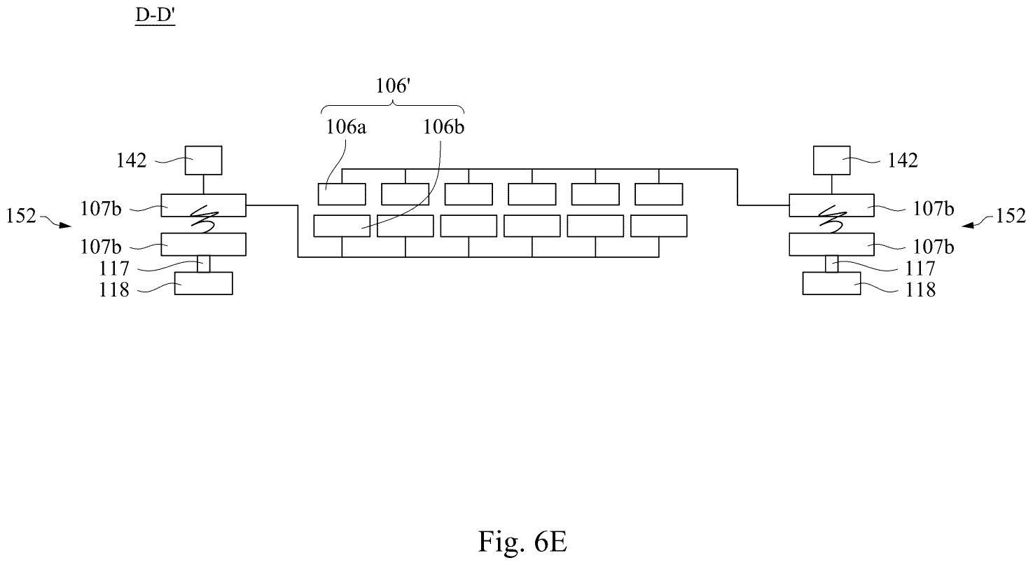

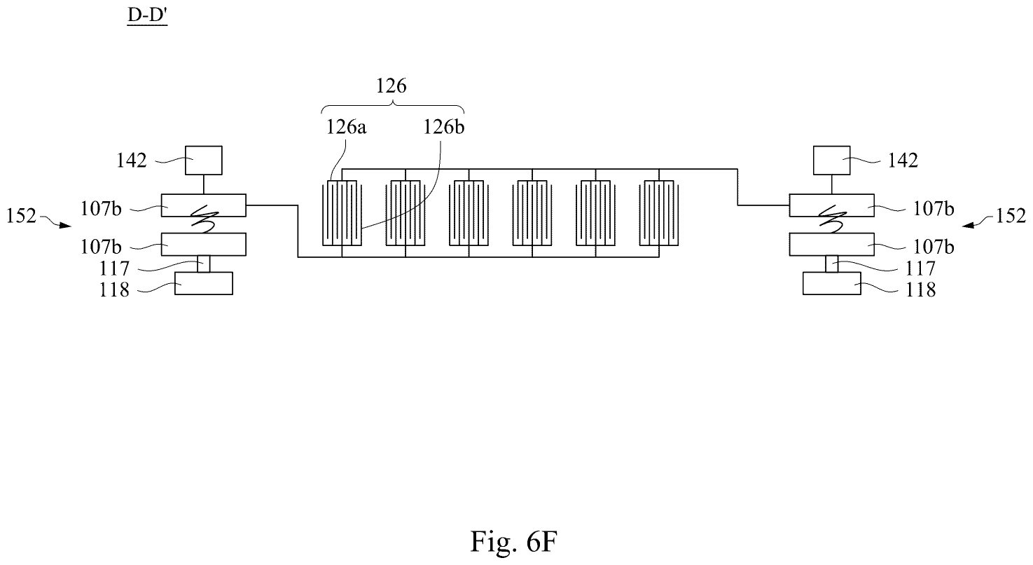

Image sensors 104 can be formed to extend from surface 102a into semiconductor substrate 102. The formation of image sensors 104 may include implantation processes. The image sensors 104 can be configured to convert light signals (photons) to electrical signals. Image sensors 104 may be photo-sensitive Metal-Oxide-Semiconductor (MOS) transistors, photo-sensitive diodes, or the like. Throughout the description, the image sensors 104 can be alternatively referred to as photo diodes, although they may be other types of image sensors. In accordance with some embodiments of the present disclosure, the image sensors 104 form an image sensor array. Each of the image sensors 104 may be in a grid unit of the grid formed by the isolation regions 103a. FIG. 2 also illustrates pixel units 105, which have at least some parts in the active regions defined by the isolation region 103a. In accordance with some embodiments of the present disclosure, the pixel unit 30 can include image sensor 104, which has an anode coupled to the electrical ground GND, and a cathode coupled to a source of transfer gate transistor 106. The gate transistor 106 can have a gate structure 106′ including gate electrode layer 106a and a gate dielectric layer 106b underlying the gate electrode layer 106a as shown in FIG. 6E. In some embodiments, the gate electrode layer 106a can be interchangeable referred to as a poly gate, and the gate dielectric layer 106b can be interchangeable referred to as an oxide layer. The drain of transfer gate transistor 106 may be coupled to a drain of reset transistor and a gate of source follower. The transfer gate transistor 106 can include a gate dielectric in contact with surface 102a of substrate 102 and a gate over the gate dielectric.

A dielectric layer 110 is formed over the surface 102b of the substrate 102. In some embodiments, the dielectric layer 110 can be formed of silicon oxide or the like transparent material. The deposition process of the dielectric layer 110 may include CVD, PECVD, ALD, or the like. Metal grids 111 and a dielectric layer 112 can be formed over the metal grids 111. The formation process of the metal grids 111 may include depositing metallic materials over the dielectric layer 110. In accordance with some embodiments of the present disclosure, the metallic materials can include an adhesion layer, and a metallic material on the adhesion layer. The adhesion layer may include a titanium layer, a titanium nitride layer, or a composite layer including a titanium layer and a titanium nitride layer over the titanium layer. The metallic material may include tungsten, chromium, or the like. After the deposition, a patterning process is performed through etching, and the metallic material and the adhesion layer are patterned as the metal grid 111. When viewed from the top of the metal grid 111, the metal grid 111 can include a first plurality of strips extending in a first direction, and a second plurality of strips extending in a second direction perpendicular to the first direction, wherein the second plurality of strips are connected to the first plurality of strips. The grid openings in metal grid 111 can further overlap the grid openings of the isolation region 103a, so that light can pass through, and confined in, the openings to reach the underlying image sensors 104. After the formation of the metal grid 111, dielectric layer 112 can be deposited. In accordance with some embodiments of the present disclosure, dielectric layer 112 can be formed of silicon oxide or the like transparent material. The dielectric layer 112 may be planarized in a CMP process or a mechanical polish process, so that its top surface is planar.

An opening 113 can be formed by etching dielectric layers formed on the backside of semiconductor substrate 102, and then etching-through semiconductor substrate 102 and the isolation regions 103b. A metal layer can be formed in the opening 113 and in contact with the metal lines/vias 107b. In accordance with some embodiments of the present disclosure, the metal layer can be formed of or comprises copper, AlCu, or the like. The formation method may include, for example, PVD, CVD, or like methods. Subsequently, the metal layer can be patterned to form metal pad 114.

Color filters 115 can be formed, and micro-lenses 116 can then be formed over the color filters 115. Each of image sensors 104 can be aligned to one of color filters 115 and one of micro-lenses 116. The image sensor chip 101 (and corresponding wafer 100) can be thus formed. There may be a protection layer (not shown) formed on the micro-lenses 116, for example, by depositing a conformal silicon oxide layer.

Referring again back to FIG. 2, a front-side interconnect structure 107 can be formed over semiconductor substrate 102. The front-side interconnect structure 107 can be used to electrically interconnect the devices in image sensor chip 101, and connect to other package components. The front-side interconnect structure 107 can include dielectric layers 107a, and metal lines/vias 107b in dielectric layers 107a. Throughout the description, the metal lines/vias 107b in a same dielectric layer 107a are collectively referred to as being a metal layer. The front-side interconnect structure 107 may include a plurality of metal layers. In accordance with some embodiments of the present disclosure, dielectric layers 107a can include low-k dielectric layers. The low-k dielectric layers have low k values, for example, lower than 3.8, and possibly lower than about 3.0.

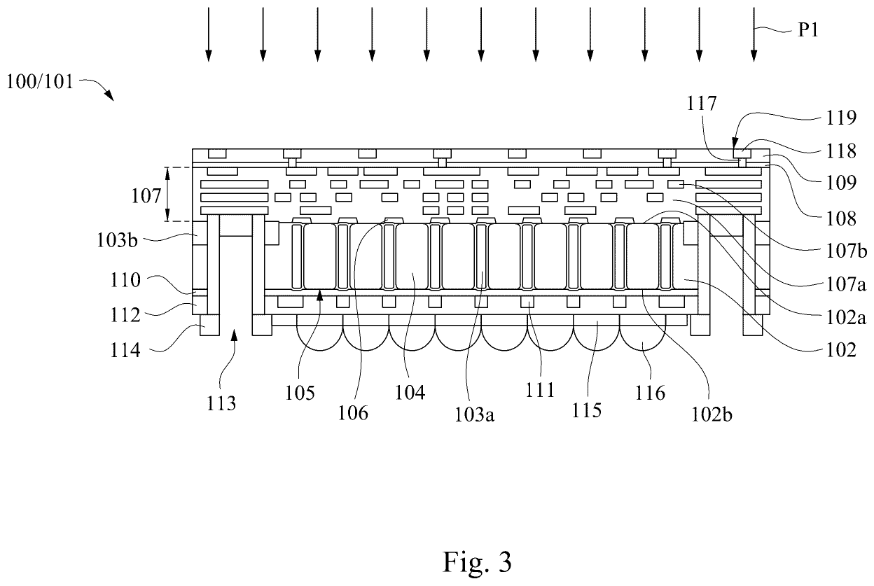

Reference is made to FIGS. 2 and 3. Bonding pads 118 and vias 117 can be further formed over the front-side interconnect structure 107. The bonding pad 118 can be directly connected to one or more underlying metal lines/vias 107b in the wafer 100, and can provide an electrical connection between the wafer 100 and the wafer 200 when the wafers are arranged in a face to face configuration. In some embodiments, the bonding pads 118 may be formed of or comprise copper. The bonding pads 118 may also include barrier layers encircling the copper. The top surfaces of bonding pads 118 may be coplanar with the top surface of the surface dielectric layer 109. Specifically, the surface dielectric layer 109 is formed as a top dielectric layer of wafer 100 over the interconnect structure 107. The surface dielectric layer 109 may be formed of non-low-k dielectric materials having k values equal to or greater than about 3.8. In accordance with some embodiments of the present disclosure, the surface dielectric layer 109 is formed of or comprises silicon oxide. A contact etch stop layer 108 can be formed over the front-side interconnect structure 107 prior to for forming the surface dielectric layer 109. The contact etch stop layer 108 may be formed of silicon oxide, silicon nitride, silicon carbo-nitride, or the like, or the multi-layers thereof. The contact etch stop layer 108 may be formed using a conformal deposition method such as Atomic Layer Deposition (ALD) or Chemical Vapor Deposition (CVD), for example. Inter-Layer.

Subsequently, the bonding pads 118 and vias 117 can be formed using photolithography techniques to deposit and pattern a photoresist material on the surface dielectric layer 109. An etch process, such as an anisotropic dry etch process, may be used to create openings 119 in the surface dielectric layer 109. The openings 119 may be lined with a diffusion barrier layer and/or an adhesion layer (not shown), and filled with a conductive material 118′ (see FIG. 2). Subsequently, a planarization process P1 (e.g., CMP) can performed to remove the excessive diffusion barrier and the conductive material 118′ until the surface dielectric layer 109 is exposed. The diffusion barrier layer comprises one or more layers of TaN, Ta, TiN, Ti, CoW, or the like, and the conductive material 118′ comprises copper, tungsten, aluminum, silver, and combinations thereof, or the like, thereby forming the bonding pads 118 and the vias 117 as illustrated in FIG. 3. In some embodiments, the bonding pads 118 can be also interchangeable referred to as metal pads or conductive pads.

In some embodiments, the etch process for the creation of openings 119 in the surface dielectric layer 109, an anisotropic dry etch process can be employed. The etch process can be directional, creating vertical sidewalls for precise vias and bonding pads. A high-density plasma etch systems can be used. By way of example and not limitation, the etch process can use gases include fluorocarbons (e.g., CF₄, CHF₃) for silicon oxide etching, combined with oxygen or argon to optimize the etch profile and rate. In some embodiments, the chamber pressure and plasma power are controlled to adjust the etch rate and directionality.

In some embodiments, the planarization Process P1 (e.g., CMP) can use a mixture containing abrasive particles (e.g., silica or ceria) suspended in a chemically reactive solution. The particle size and concentration can be tailored to achieve the desired material removal rate and surface finish. In some embodiments, the pad used in the planarization Process P1 can be a polyurethane-based material, and its hardness, porosity, and compressibility are selected based on the specific requirements of the material being polished. In some embodiments, the pressure applied (e.g., downforce) and the relative speed between the wafer 100 and the pad can affect the rate of material removal and the quality of the planarization. In some embodiments, the pH and composition of the slurry can be adjusted based on the materials being polished to optimize the chemical contribution to the material removal process.

The etch process (e.g., creating openings 119) and planarization processes P1 may introduce charges that may accumulate on the wafer surface. These charges can negatively impact the devices on the wafer 100, potentially leading to issues like device instability, leakage currents, or even permanent damage. In some embodiments, the etch process used for creating the openings 119 can involve dry etching techniques, such as a reactive ion etching (RIE), which can generate plasma. The etch process may include a plasma-based etching including high-energy ions and electrons. When these charged particles strike the wafer surface, they can lead to charging effects. The disparity in the arrival rate of ions and electrons at the surface can lead to a net charge accumulation. In some embodiments, the ions in the plasma remove material from the wafer 100 but can also implant themselves into the dielectric or semiconductor layers, creating localized charge centers. In some embodiments, the physical bombardment by ions can damage the lattice structure of the semiconductor, creating traps and defects that can later capture and release charges.

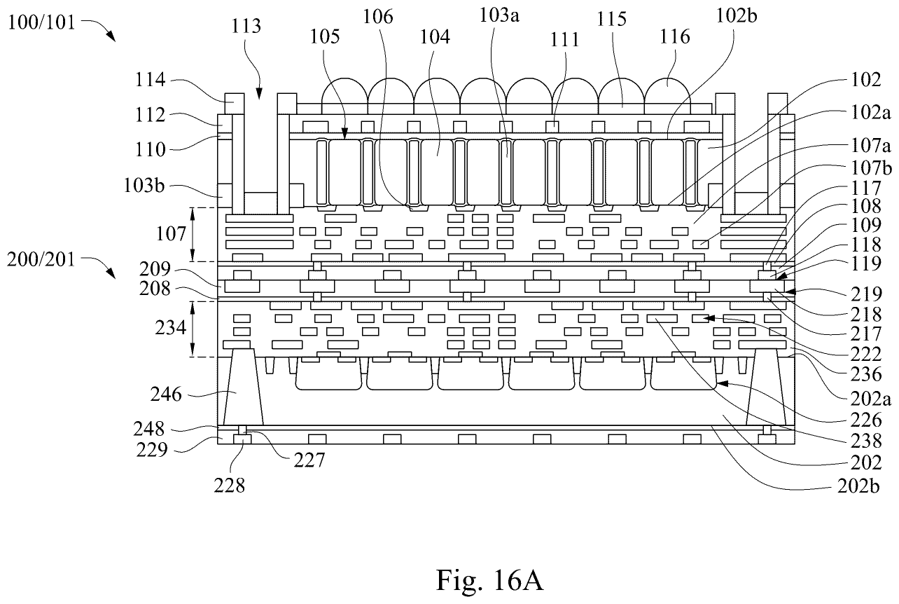

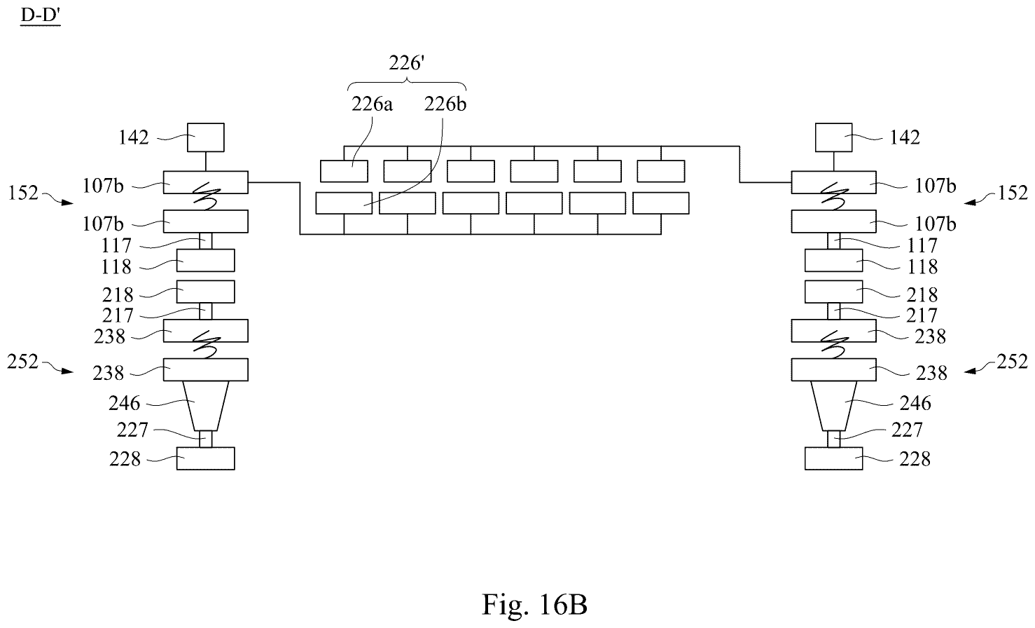

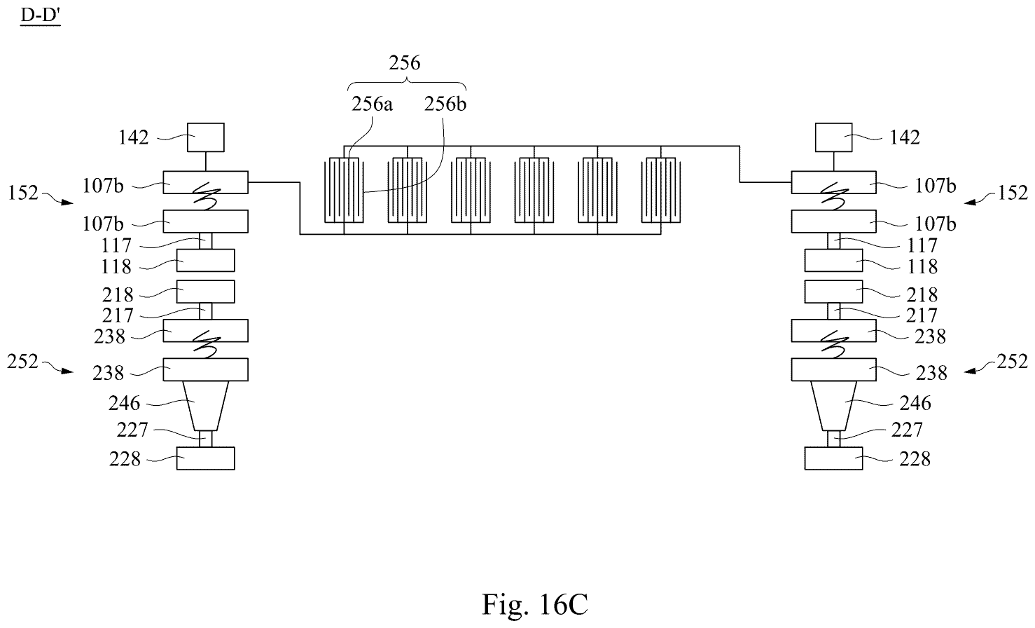

The planarization process P1 can involve mechanical abrasion and chemical action to flatten and smooth the wafer surface. While this process may also lead to charge accumulation. The friction between the pad, the wafer 100, and the abrasive slurry particles can generate static electricity, leading to tribocharging. The chemical components of the slurry might interact electrochemically with the materials on the wafer surface, leading to charge transfer processes. The accumulated charge in the gate oxide of the transistor can shift the threshold voltage, leading to altered device behavior. High localized electric fields due to charging can lead to premature breakdown of gate oxides. In some embodiments, a process control monitoring (PCM) (see FIGS. 16A-16C) can be performed on the bonded structure of the wafers 100, 200, and/or 300 to detect and manage charge accumulation at the interface between the wafers 100 and 200, and then a combination of testing techniques and equipment adjustments can be employed. These methods can identify the presence of charges, their impact on device performance, and the adjustments to process parameters or tool settings to mitigate unwanted charges in subsequent manufacturing processes.

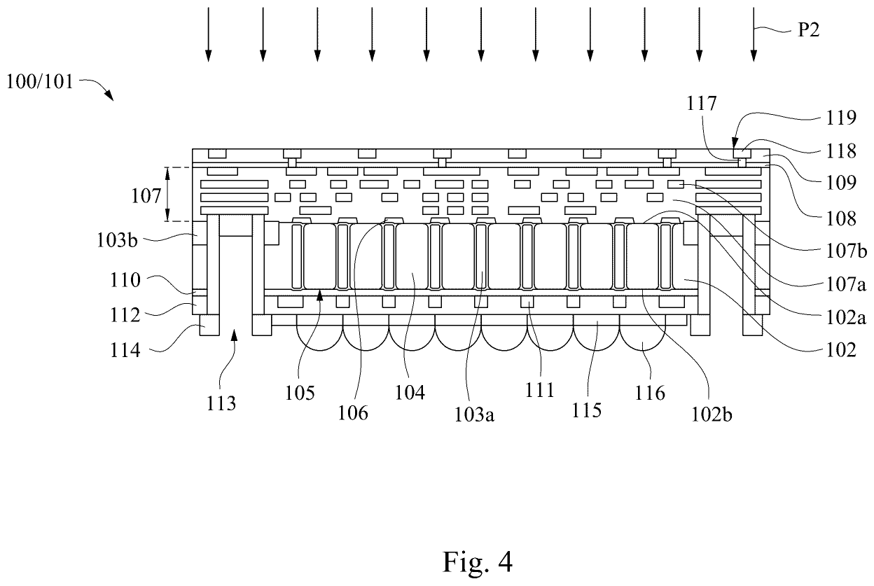

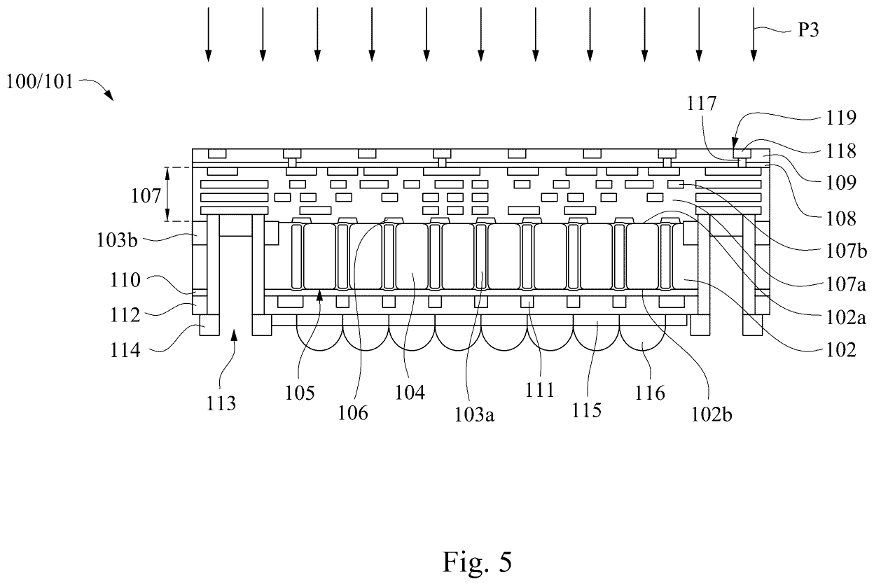

Reference is made to FIGS. 4 and 5. To prepare the wafer 100 for bonding, a surface cleaning process P2 (see FIG. 4) and a surface activation process P3 (see FIG. 5) of the wafer 100 may be performed. As shown in FIG. 4, the surface cleaning process P2 can be performed to remove CMP slurry and native oxide layers from surfaces of the wafer 100. The surface cleaning process P2 may include methods with direct and non-direct contact with the surfaces of the wafer 100, such as cryogenic cleaning, mechanical wiping and scrubbing, etching in a gas, plasma or liquid, ultrasonic and megasonic cleaning, laser cleaning, and the like. In some embodiments, the cryogenic cleaning may uses liquid nitrogen or argon to freeze and then dislodge contaminants. Subsequently, the wafer 100 may be rinsed in de-ionized (DI) water and dried using a spin dryer or an isopropyl alcohol (IPA) dryer. In some embodiments, the wafer 100 may be cleaned using RCA clean, or the like. As shown in FIG. 5, the surface activation process P3 may include suitable processes, such as plasma etch, which may be performed after the wafer cleaning process, from the surfaces of the wafer 100. The plasma etch process can use gases including CF₄, SF₆, or O₂, depending on the specific material to be removed.

The surface cleaning process P2 (see FIG. 4) and surface activation process P3 (see FIG. 5) may introduce charges that may accumulate on the wafer surface. These charges can negatively impact the devices on the wafer 100, potentially leading to issues like device instability, leakage currents, or even permanent damage. In some embodiments, the rapid temperature changes in the cryogenic cleaning of the surface cleaning process P2 can lead to triboelectric effects, where different materials gain or lose electrons. In some embodiments, physical contact and friction between the cleaning tools and the wafer surface can generate static electricity in the mechanical wiping and scrubbing of the surface cleaning process P2. In some embodiments, plasma cleaning processes of the surface cleaning process P2 may involve ionized gases that can deposit charges onto the wafer surface. The surface activation process P3 may contribute to charge accumulation. The use of reactive ions in the surface activation process P3 can leave a charged residue on the wafer surface.

In some embodiments, a process control monitoring (PCM) (see FIGS. 16A-16C) can be performed on the bonded structure of the wafers 100, 200, and/or 300 to detect and manage charge accumulation at the interface between the wafers 100 and 200, and then a combination of testing techniques and equipment adjustments can be employed. These methods can identify the presence of charges, their impact on device performance, and the adjustments to process parameters or tool settings to mitigate unwanted charges in subsequent manufacturing processes.

Reference is made to FIGS. 6A-6F. FIGS. 6A-6F illustrate process control monitors (PCMs) used in semiconductor manufacturing to evaluate and ensure the integrity and performance of both active and passive devices on the wafer 100. In some embodiments, the PCM can track various fabrication steps such as doping, etching, and deposition that affect active devices (e.g., transistors 106) performance. It can help identify any deviations in the electrical characteristics of transistors, such as threshold voltage and drive current. By embedding test structures that mimic the characteristics of actual transistors on the wafer 100, the PCM can allow for real-time measurement of electrical properties under various test conditions. This includes testing for leakage current, gate oxide integrity, and other transistor parameters that directly impact device reliability and performance. The PCM can also track the capacitance values and leakage currents of capacitors integrated into the wafer 100. It can help verify that passive devices (e.g., capacitors 126 shown FIG. 6F) meet the design specifications and ensure their proper function in the circuit. By comparing the measured values of capacitance and leakage with predetermined standards, the PCMs can identify any anomalies or defects in the active/passive components, aiding in early detection of potential failure mechanisms.

Specifically, the structure shown in FIG. 6A is “flipped” upside down relative to the structure shown in FIG. 5. FIGS. 6B and 6C illustrate a perspective view and a top view of the wafer 100, in accordance with some embodiments of the present disclosure. FIG. 6D illustrates a partial enlarged view of a test line on the wafer 100 in FIG. 6C in accordance with some embodiments of the present disclosure. FIGS. 6E and 6F illustrate cross-sectional views of obtained from the reference cross-sections D-D′ in FIG. 6D in accordance with some embodiments of the present disclosure. FIG. 6E illustrates a schematic view of a process control monitor (PCM) including transistors in accordance with some embodiments of the present disclosure. FIG. 6F illustrates a schematic view of a PCM including capacitors in accordance with some embodiments of the present disclosure. In some embodiments, the PCM can be performed from the back-side of the wafer 100.

As shown in FIG. 6B, a wafer acceptance test tool can be configured to test a chip 101 formed on the wafer 100. As shown in FIG. 6C, the wafer 100 may include a plurality of chips 101 arranged in a grid pattern, which includes a plurality of rows and columns of chips 101. Each row of the chips 101 is separated by horizontal scribe lines 120, and each column of dies or chips are separated by vertical scribe lines 120′. Individual chips 101 within the wafer 100 may contain circuitry. The chips 101 can be separated by a sawing operation performed through the scribe lines (e.g., the scribe lines 120 and 102′). In some embodiments, the test line area 121 can be removed during dicing of the wafer 100. The chips 101 on the wafer 100 may include several basic circuit elements, which can be interconnected to form semiconductor structures to form logic or other functions. In some embodiments, the basic circuit elements may include active devices such as transistors and passive devices such as resistors, capacitors, inductors, or a combination thereof. In an exemplary semiconductor fabrication process, each basic circuit element may need to be tested and evaluated at selected steps, or at the end, of the formation so as to maintain and assure the device quality.

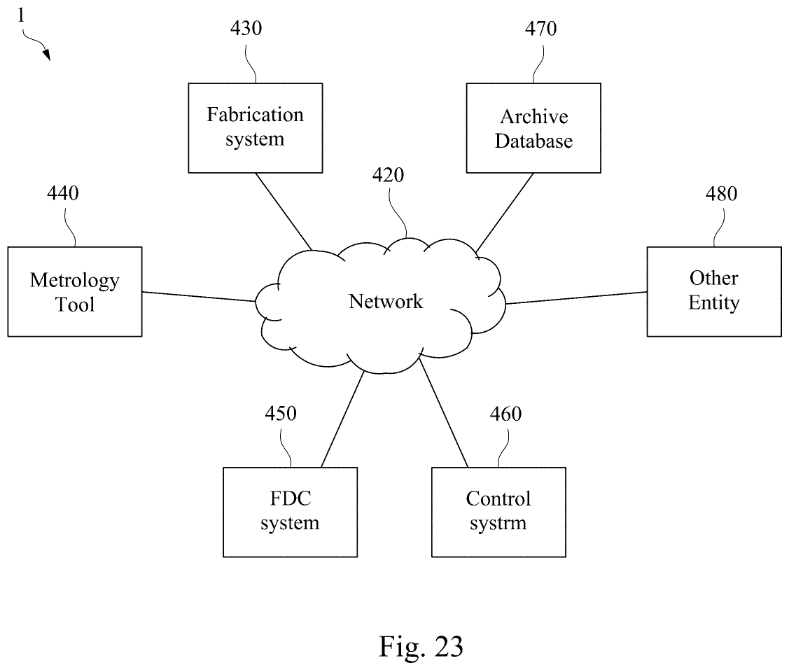

A test line area 121 is on the wafer 100 as shown in FIGS. 6B and 6C. The test line area 121 in FIG. 6D can be a schematic block diagram of a portion of the wafer 100 denoted by the dashed box as shown in FIG. 6C. In some embodiments, one or more of the test line areas 121 can be formed in the scribe lines 120 (see FIG. 6C). In some embodiments, one or more of the test line areas 121 can be formed in the scribe lines 120 and 120′. In alternative embodiments, one or more of the test line areas 121 can be formed inside the chips 101. In some embodiments, the test line area 121 can be used to monitor the quality of wafer processing in manufacturing, for example, to observe the device variation on the wafer 100. The test line area 121 may include one or more probe pads 142 exposed through the top surface of the wafer 100. In some embodiments, the number of the probe pads 142 depends on the design and area. For example, but not limited to, one test line area 121 may include twenty-two test probe pads. The probe of the metrology device 440 (see FIG. 23) will contact the probe pads 142 to measure the electrical properties.

As shown in FIGS. 6E and 6F, the structure within the test line area 121 can be fabricated concurrently with the structure in chips 101, utilizing the same processes and materials, ensuring that both areas are fundamentally similar, allowing them to correspond directly to one another in terms of layout and material properties. To maintain consistency and clarity, similar components within both the test line area 121 and the chips 101 are identified using the same reference numerals. Additionally, the test line area 121 incorporates a process control monitoring (PCM) pattern that is integrated with a design of experiments (DOE) pattern, enhancing the capability to systematically evaluate and optimize the manufacturing process. The test line area 121 can have a semiconductor structure formed thereon, and the semiconductor structure may include a dielectric stack (not shown), the probe pads 142 formed on a top of the dielectric stack, a test device (e.g., gate structure as shown in FIG. 6E, a capacitor as shown in FIG. 6F) embedded in the dielectric stack and electrically connected to the corresponding probe pads, and metal strings 152 along a vertical direction and electrically connecting the probe pad 142 to the test device. In some embodiments, the dielectric stack may include the dielectric layer 107a, the contact etch stop layer 108, the surface dielectric layer 109. In some embodiments, the semiconductor structure can be interchangeably referred to as a test line structure. In some embodiments, the metal strings 152 and the test device can be collectively referred to as a PCM pattern.

The probe pads 142 are formed on a top of the dielectric stack. In some embodiments, the probe pads 142 of the semiconductor structure are configured to electrically connect to an external circuit or probes of a probe card to check the quality of the integrated circuit, as part of the wafer acceptance test. In some embodiments, the probe pads 142 of the semiconductor structure are configured to apply test stimuli to a corresponding test device (e.g., gate structure as shown in FIG. 6E, a capacitor as shown in FIG. 6F). In some embodiments, the probe pad 142 can have a square shape from a top view (see FIG. 6D). The probe pad 142 can be, but are not limited to, round, oval, rectangular, square or other desired shape. In some embodiments, the opposing edges of each of the probe pads 142 are either parallel or perpendicular to the longitudinal edges of the scribe line 120 (see FIG. 6D). In some embodiments, the probe pads 142 may be rotated such that the opposing edges thereof are not aligned with the longitudinal edges of the scribe line 120. The probe pads 142 are illustrated for clarity and simplicity, but such example is intended to be illustrative only, and is not intended to be limiting to the embodiments. A person ordinarily skilled in the art would readily understand that any suitable number of the probe pads 142 may alternatively be utilized, and all such combinations are fully intended to be included within the scope of the embodiments. Additionally, while the probe pads 142 are illustrated as having similar features, this is intended to be illustrative and is not intended to limit the embodiments, as the probe pads 142 may have similar structures or different structures in order to meet the desired functional capabilities. In some embodiments, each of the probe pad 142 may include conductive material such as gold (Au), silver (Ag), copper (Cu), nickel (Ni), tungsten (W), aluminum (Al), tin (Sn), tantalum (Ta), tantalum nitride (TaN), aluminum copper (AlCu) and/or alloys thereof.

The test device is designed to monitor different process parameters or to evaluate different device structures and circuit products of the wafer 100. In some embodiments, the test device can be selected from a group consisting of MOS devices, field MOS devices, diode devices, capacitors, resistors, inductors, contact/via chains, gate/field dielectric integrity devices, reliability devices, memory devices, user designed application-specific circuit structures, and the like. In some embodiments, the test device may be a device similar to a device formed in a die. In some embodiments, the test device can disposed in the dielectric stack. In some embodiments, the test devices (e.g., gate structure as shown in FIG. 6E, a capacitor as shown in FIG. 6F) can be electrically coupled to the corresponding probe pad 142 through the metal string 152. In some embodiments, a wafer acceptance test method can include providing several test devices distributed in a periphery region of the chip 101, which is desired to be tested. A module of the test devices is selected and each test device of the selected module is respectively used for a test of a different property of the wafer, such as threshold voltage (VTH) or saturate current (IDSAT).

In some embodiments, the metal string 152 can be configured to electrically connect the test device to the probe pad 142. In some embodiments, each of the metal string 152 extends along a direction from a level of the probe pad 142 to the bonding pad 118. In some embodiments, each of the metal strings 152 can include the metal lines/vias 107b, the via 117, and bonding pad 118 connected in sequence. In FIGS. 6E and 6F, the metal lines/vias 107b of the front-side interconnect structure 107 illustrated only show the uppermost and lowermost metal layers within the metal strings 152. Other metal lines/vias 107b within these strings 152 are represented schematically as curves and are not explicitly illustrated in the drawings. This representation can simplify the visual complexity of the figures while indicating the connectivity and alignment through the dielectric stack. In some embodiments, the metal string 152 can be embedded in one or more sublayers of the dielectric stack. For each of the vias 153, a sublayer of the dielectric stack 141 is etched with a pattern, a conductive material is deposited over the sublayer, and a top portion of the deposited conductive material is removed by a chemical mechanical planarization (CMP) process. The overall process can be used to make the metal string 152, while a dual damascene process can be used to make other interlayer connections. In some embodiments, each of the metal string 152 may include conductive material such as gold (Au), silver (Ag), copper (Cu), nickel (Ni), tungsten (W), aluminum (Al), tin (Sn), tantalum (Ta), tantalum nitride (TaN), aluminum copper (AlCu) and/or alloys thereof.

Reference is made to FIGS. 6E and 6F, the process control monitor on the test devices (e.g., gate structure 106′ as shown in FIG. 6E, capacitor 126 as shown in FIG. 6F) in the wafer 100 can ensuring the quality and reliability of these fundamental semiconductor components through various stages of device fabrication. As shown in FIG. 6E, the PCM can be performed on active devices (e.g., gate structure 106′). In some embodiments, the off-state leakage current can be measured to ensure that the gate structure 106′ does not consume excessive power when it should be off. Additionally, the PCM can measure the threshold voltage to ensure it aligns with the designed specifications of the gate structure 106′, and the drive current can be measured under various gate voltages to assess the transistor's operating characteristics. As shown in FIG. 6F, the PCM can be performed on the capacitors 126 in the wafer 100. The capacitor 126 can have an electrode 126a and an electrode 126a. The leakage current can be measured for assessing the health of the dielectric material used in the capacitors 126. In some embodiments, the PCM may apply high voltage stress tests on the capacitors 126 to ensure that the capacitors can withstand transient conditions without breakdown.

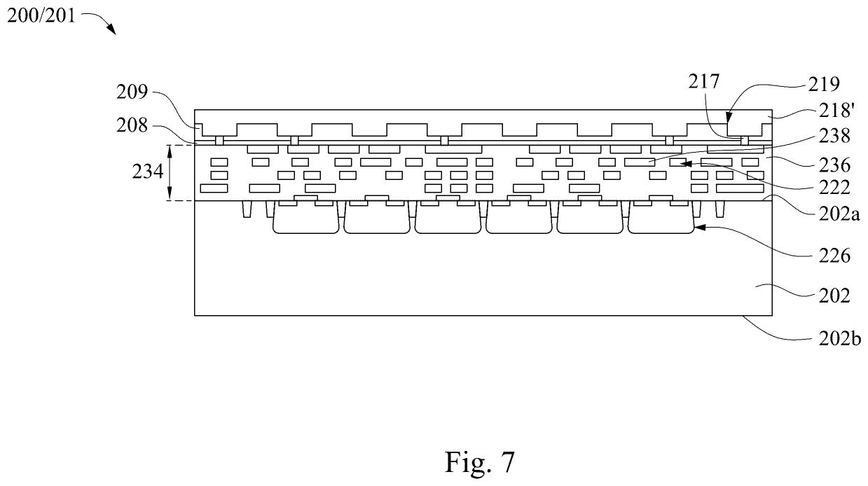

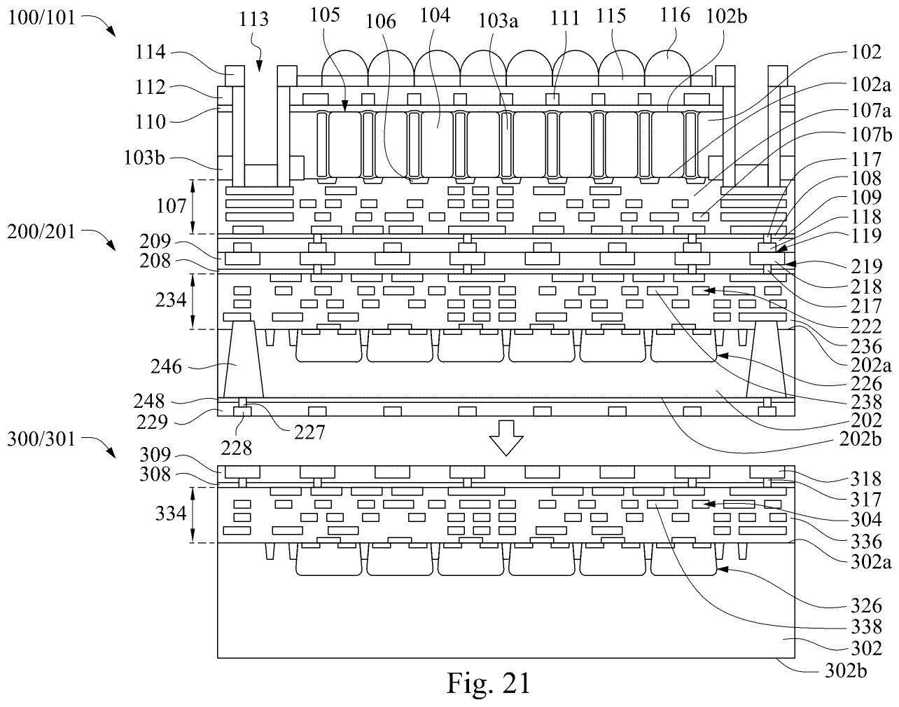

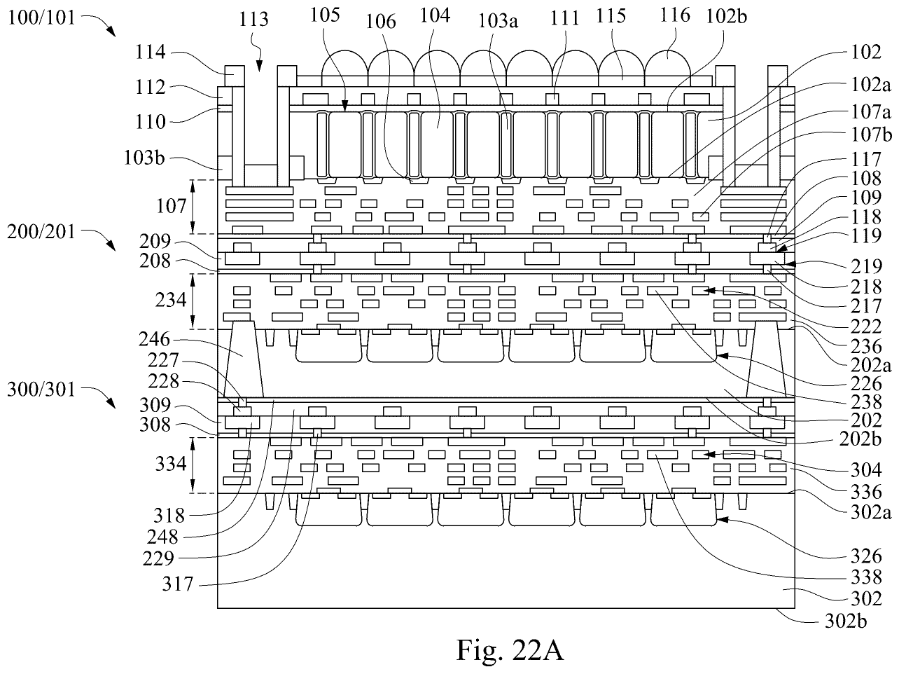

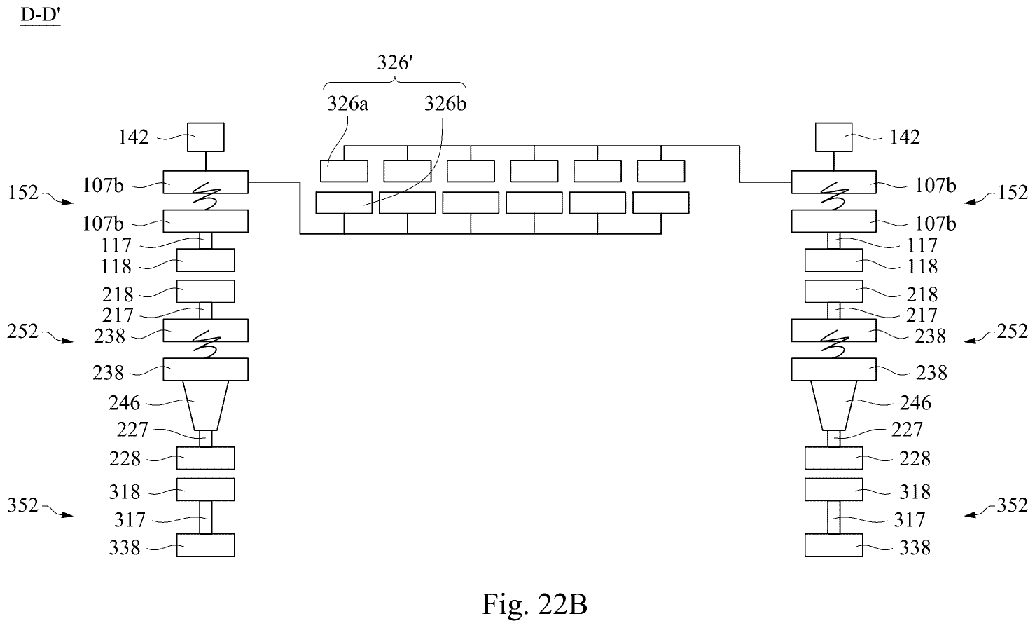

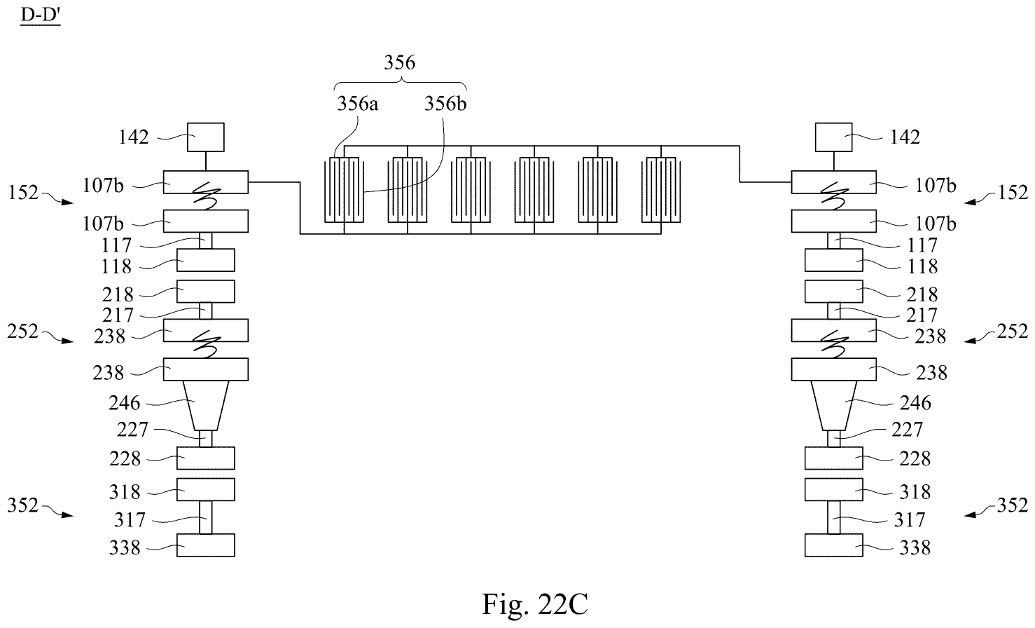

Reference is made to FIG. 7. FIG. 7 illustrates a cross-sectional view of device chip 201, which is in the wafer 200 that comprises a plurality of identical device chips identical to the device chip 201. The device chip 201 can include a substrate 202. Throughout the description, a surface 202a of the substrate 202 cab be referred to as a front-side surface of the substrate 202, and a surface 202b can be referred to as a back-side surface of the substrate 202, and a logic circuit 222 formed at the front surface 202a of the substrate 202. The substrate 202 can be a silicon substrate in some embodiments. Alternatively, the substrate 202 can be formed of other semiconductor materials such as silicon germanium, silicon carbon, III-V compound semiconductor materials, or the like. In accordance with some embodiments, the logic circuit 222 can include a plurality of transistors 226. In some embodiments, the gate transistor 226 can have a gate structure 226′ as shown in FIG. 16B. In alternative embodiments, some of the logic circuits may be formed in chip 201. For example, the row decoders may be formed in the chip 201, while the analog-to-digital converters (ADCs) and the correlated double sampling (CDS) circuits are not formed in the chip 301 (see FIGS. 21 and 22A).

An interconnect structure 234 can be formed over, and electrically coupling the transistors 226 to a peripheral circuit 304 in the chip 301 (see FIGS. 21 and 22A). The interconnect structure 234 can include a plurality of metal layers in a plurality of dielectric layers 236. Metal lines/vias 238 can be disposed in dielectric layers 236. In some exemplary embodiments, the dielectric layers 236 can include low-k dielectric layers. The low-k dielectric layers may have low k values that are lower than about 3.0. The dielectric layers 236 may further include a passivation layer formed of non-low-k dielectric materials having k values greater than 3.9. In some embodiments, the passivation layer includes a silicon oxide layer, an un-doped silicate glass layer, and/or the like.

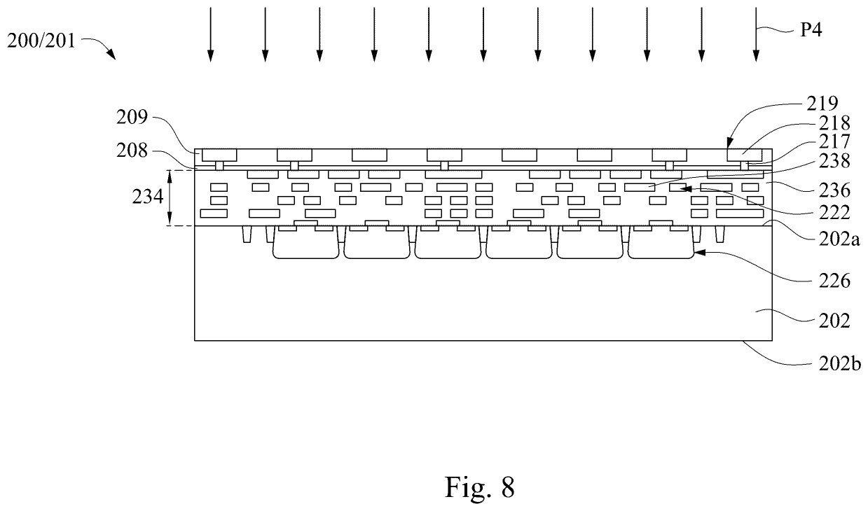

Reference is made to FIGS. 7 and 8. Bonding pads 218 and vias 217 can be further formed over the interconnect structure 234. The bonding pad 218 can be directly connected to one or more underlying metal lines/vias 238 in the wafer 200, and can provide an electrical connection between the wafer 100 and the wafer 200 when the wafers are arranged in a face to face configuration. In some embodiments, the bonding pads 218 may be formed of or comprise copper. The bonding pads 218 may also include barrier layers encircling the copper. The top surfaces of bonding pads 218 may be coplanar with the top surface of the surface dielectric layer 209. Specifically, the surface dielectric layer 209 can be formed as a top dielectric layer of the wafer 200 over the interconnect structure 234. The surface dielectric layer 209 may be formed of non-low-k dielectric materials having k values equal to or greater than about 3.8. In accordance with some embodiments of the present disclosure, the surface dielectric layer 209 can be formed of or comprises silicon oxide. A contact etch stop layer 208 can be formed over the interconnect structure 234 prior to for forming the surface dielectric layer 209. The contact etch stop layer 208 may be formed of silicon oxide, silicon nitride, silicon carbo-nitride, or the like, or the multi-layers thereof. The contact etch stop layer 208 may be formed using a conformal deposition method such as Atomic Layer Deposition (ALD) or Chemical Vapor Deposition (CVD), for example. Inter-Layer.

Subsequently, the bonding pads 218 and vias 217 can be formed using photolithography techniques to deposit and pattern a photoresist material on the surface dielectric layer 209. An etch process, such as an anisotropic dry etch process, may be used to create openings 219 in the surface dielectric layer 209. The openings 219 may be lined with a diffusion barrier layer and/or an adhesion layer (not shown), and filled with a conductive material 218′ (see FIG. 7). Subsequently, a planarization process P4 (e.g., CMP) can performed to remove the excessive diffusion barrier and the conductive material 218′ until the surface dielectric layer 209 is exposed. The diffusion barrier layer comprises one or more layers of TaN, Ta, TiN, Ti, CoW, or the like, and the conductive material 218′ comprises copper, tungsten, aluminum, silver, and combinations thereof, or the like, thereby forming the bonding pads 218 and the vias 217 as illustrated in FIG. 8.

In some embodiments, the etch process for the creation of openings 219 in the surface dielectric layer 209 can be similar to the etch process for the creation of openings 119 in the surface dielectric layer 109 (see FIG. 2), and the planarization process P4 can be similar to the planarization process P1 (see FIG. 3). That is, the etch process for the creation of openings 219 in the surface dielectric layer 209 and the planarization process P4 can correspond to the etch process for the creation of openings 119 in the surface dielectric layer 109 and the planarization process P1 and can refer to the previous figures and related description.

In some embodiments, the etch process (e.g., creating openings 219) and planarization processes P4 may introduce charges that may accumulate on the wafer surface. These charges can negatively impact the devices on the wafer 200, potentially leading to issues like device instability, leakage currents, or even permanent damage. In some embodiments, a process control monitoring (PCM) (see FIGS. 16A-16C) can be performed on the bonded structure of the wafers 100, 200, and/or 300 to detect and manage charge accumulation at the interface between the wafers 100 and 200, and then a combination of testing techniques and equipment adjustments can be employed. These methods can identify the presence of charges, their impact on device performance, and the adjustments to process parameters or tool settings to mitigate unwanted charges in subsequent manufacturing processes.

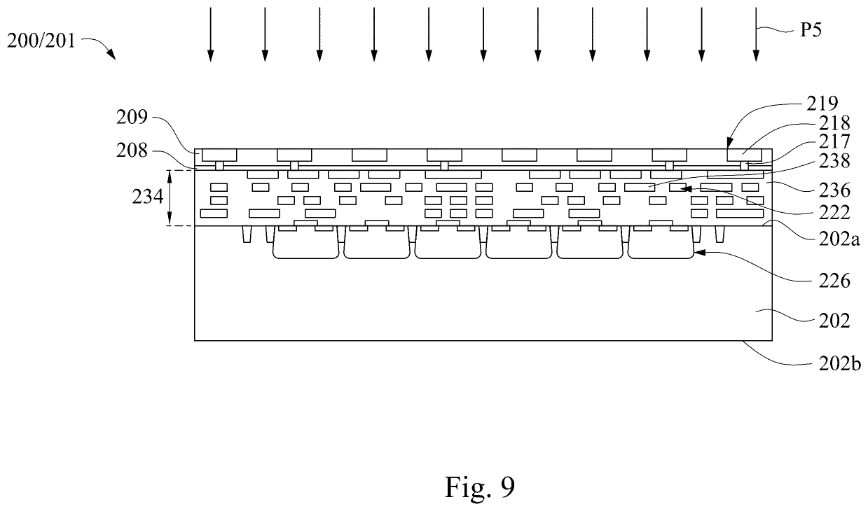

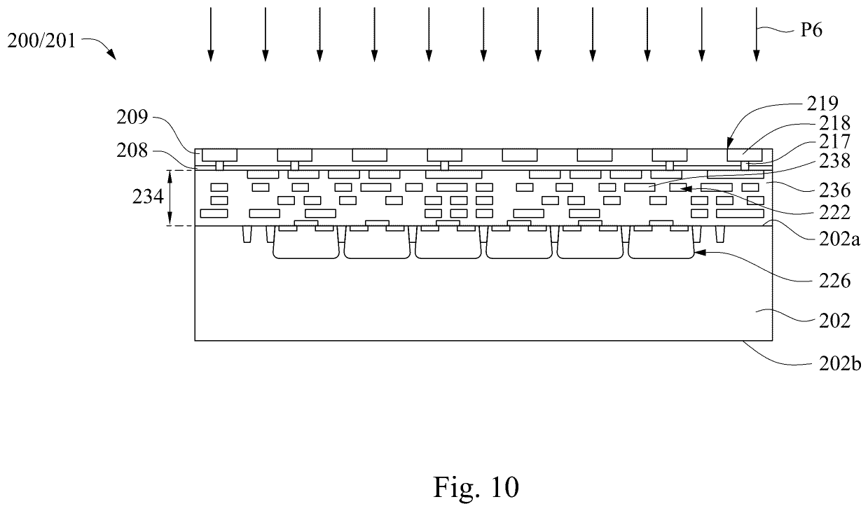

Reference is made to FIGS. 9 and 10. To prepare the wafer 200 for bonding, a surface cleaning process P5 (see FIG. 9) and a surface activation process P6 (see FIG. 10) of the wafer 200 may be performed. As shown in FIG. 9, the surface cleaning process P5 can be performed to remove CMP slurry and native oxide layers from surfaces of the front-side of the wafer 200. As shown in FIG. 10, the surface activation process P6 may include suitable processes, such as plasma etch, which may be performed after the wafer cleaning process, from the front-side surface of the wafer 200. The surface cleaning process P5 and the surface activation process P6 can be similar to the surface cleaning process P2 (see FIG. 4) and the surface activation process P3 (see FIG. 5). That is, the surface cleaning process P5 and the surface activation process P6 can correspond to the surface cleaning process P2 and the surface activation process P3 and can refer to the previous figures and related description.

In some embodiments, the surface cleaning process P5 (see FIG. 9) and surface activation process P6 (see FIG. 10) may introduce charges that may accumulate on the wafer surface. These charges can negatively impact the devices on the wafer 200, potentially leading to issues like device instability, leakage currents, or even permanent damage. In some embodiments, a process control monitoring (PCM) (see FIGS. 16A-16C) can be performed on the bonded structure of the wafers 100, 200, and/or 300 to detect and manage charge accumulation at the interface between the wafers 100 and 200, and then a combination of testing techniques and equipment adjustments can be employed. These methods can identify the presence of charges, their impact on device performance, and the adjustments to process parameters or tool settings to mitigate unwanted charges in subsequent manufacturing processes.

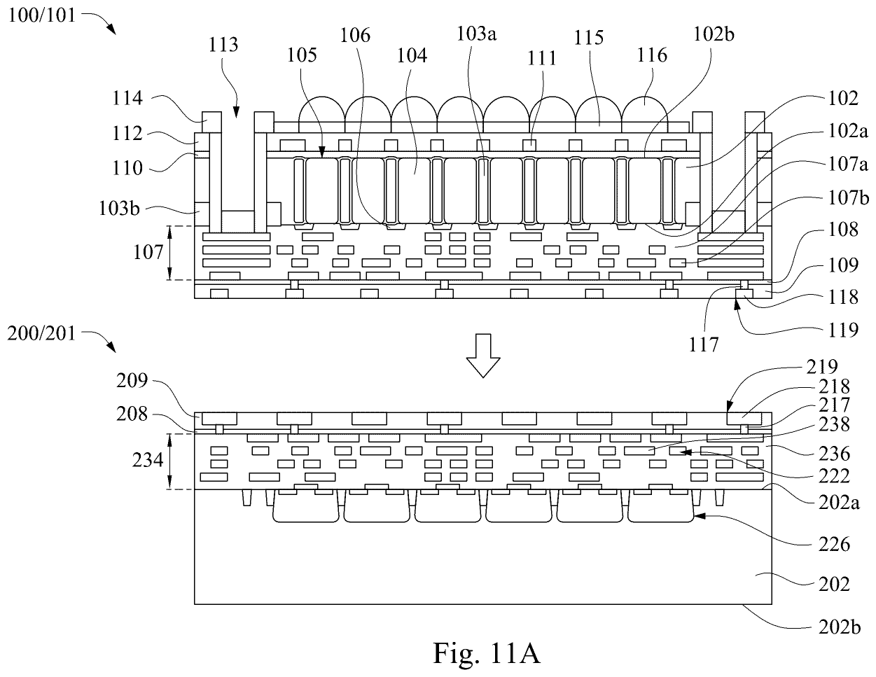

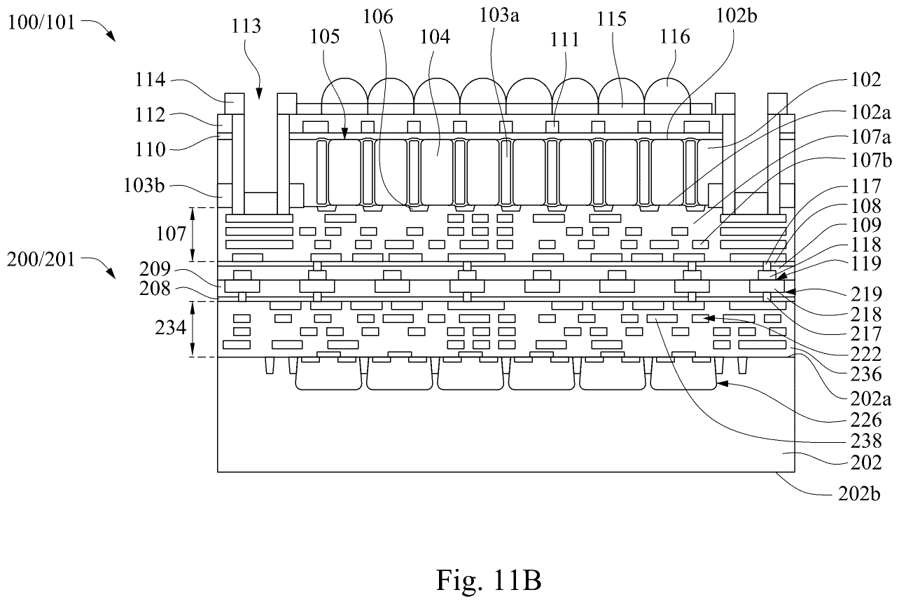

Reference is made to FIGS. 11A and 11B. The wafer 100 is bonded to the wafer 200. In some embodiments, the wafer 100 and the wafer 200 may be bonded using, for example, a direct bonding process such as metal-to-metal bonding (e.g., copper-to-copper bonding), dielectric-to-dielectric bonding (e.g., oxide-to-oxide bonding), metal-to-dielectric bonding (e.g., oxide-to-copper bonding), hybrid bonding (e.g., simultaneous metal-to-metal and dielectric-to-dielectric bonding), any combinations thereof and/or the like.

For example, the wafer 100 and the wafer 200 may be bonded using hybrid bonding. The bonding pads 118 of the wafer 100 are respectively aligned to the bonding pads 218 of the wafer 200. For example, in some embodiments, the surfaces of the wafer 100 and the wafer 200 may be put into physical contact at room temperature, atmospheric pressure, and ambient air, and the bonding pads 118 and the bonding pads 218 may be bonded using direct metal-to-metal bonding. At the same time, the surface dielectric layer 109 of the wafer 100 and the surface dielectric layer 209 of wafer 200 may be bonded using direct dielectric-to-dielectric bonding. Subsequently, annealing may be performed to enhance the bonding strength between the wafer 100 and the wafer 200. As a result of the bonding, the image sensors 104, the transfer gate transistors 106, and the transistors 226 are coupled to form a plurality of pixel units. It should be noted that the bonding may be performed at wafer level, wherein the wafer 100 and the wafer 200 are bonded together, and are then singulated into separated dies. Alternatively, the bonding may be performed at the die-to-die level, or the die-to-wafer level.

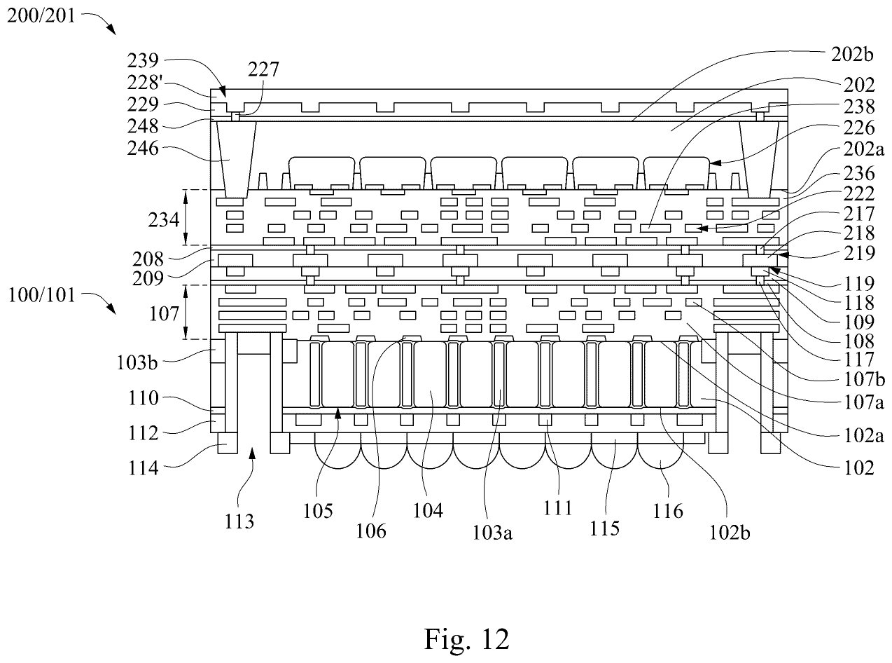

Reference is made to FIG. 12. The structure shown in FIG. 12 is “flipped” upside down relative to the structure shown in FIG. 11B. The back-side of the substrate 202 can be thinned down to an optimized thickness before the formation of back-side through substrate bias (BTSVs) 246. The formation of the BSVs 246, or referred to as through silicon vias (TSVs), may include the substrate 120, and some dielectric layers in the chip 200 to form a TSV opening, until the metal lines/vias 238 are exposed. The metal lines/vias 238 may be in the bottom metal layer that is closest to the transistors 226, or may be in a metal layer that is further away from the transistors 226 than the bottom metal layer. The TSV openings can be then filled with a conductive material such as a metal or metal alloy, followed by a chemical mechanical polish (CMP) process to remove excess portions of the conductive material. As a result of the CMP process, the top surfaces of the BTSVs 246 may be substantially level with the back-side surface 202b of the substrate 202, which enables the hybrid bonding of the wafer 200 to wafer 300 as shown in FIG. 21.

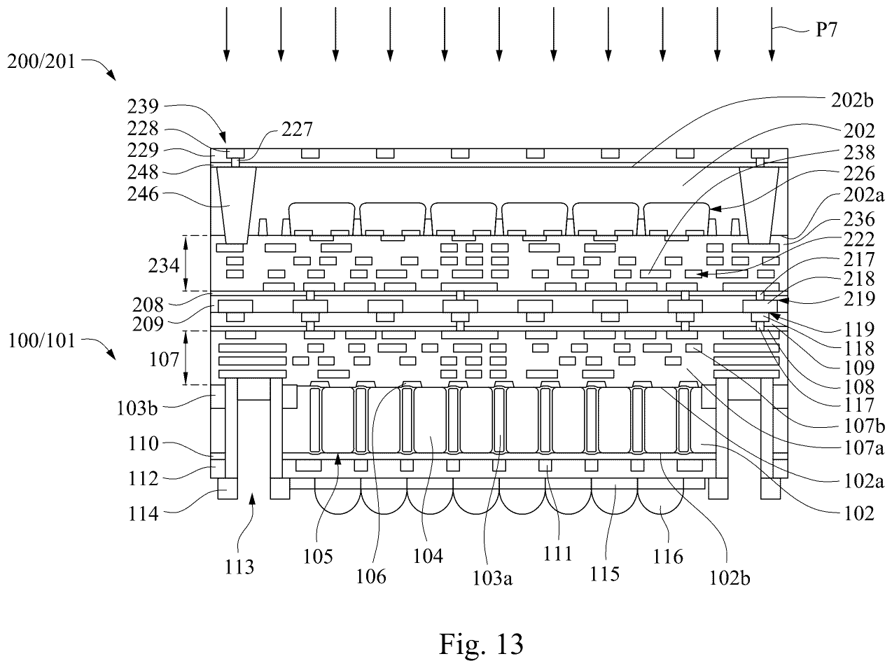

Reference is made to FIGS. 12 and 13. Bonding pads 228 and vias 227 can be further formed over the back-side of the substrate 202. The bonding pad 228 can be directly connected to one or more metal lines/vias 238 in the wafer 200 through the BTSVs 246, and can provide an electrical connection between the wafer 200 and the wafer 300 (see FIG. 21) when the wafers are arranged in a face to face configuration. In some embodiments, the bonding pads 228 may be formed of or comprise copper. The bonding pads 228 may also include barrier layers encircling the copper. The top surfaces of bonding pads 228 may be coplanar with the top surface of the surface dielectric layer 229. Specifically, the surface dielectric layer 229 can be formed as a bottom dielectric layer of the wafer 200 over the backside surface 202b of the substrate 202. The surface dielectric layer 229 may be formed of non-low-k dielectric materials having k values equal to or greater than about 3.8. In accordance with some embodiments of the present disclosure, the surface dielectric layer 229 can be formed of or comprises silicon oxide. A contact etch stop layer 248 can be formed over the backside surface 202b of the substrate 202 prior to for forming the surface dielectric layer 229. The contact etch stop layer 248 may be formed of silicon oxide, silicon nitride, silicon carbo-nitride, or the like, or the multi-layers thereof. The contact etch stop layer 248 may be formed using a conformal deposition method such as Atomic Layer Deposition (ALD) or Chemical Vapor Deposition (CVD), for example. Inter-Layer.

Subsequently, the bonding pads 228 and vias 227 can be formed using photolithography techniques to deposit and pattern a photoresist material on the surface dielectric layer 229. An etch process, such as an anisotropic dry etch process, may be used to create openings 239 in the surface dielectric layer 229. The openings 239 may be lined with a diffusion barrier layer and/or an adhesion layer (not shown), and filled with a conductive material 228′ (see FIG. 7). Subsequently, a planarization process P7 (e.g., CMP) can performed to remove the excessive diffusion barrier and the conductive material 228′ until the surface dielectric layer 229 is exposed. The diffusion barrier layer comprises one or more layers of TaN, Ta, TiN, Ti, CoW, or the like, and the conductive material 228′ comprises copper, tungsten, aluminum, silver, and combinations thereof, or the like, thereby forming the bonding pads 228 and the vias 227 as illustrated in FIG. 13.

In some embodiments, the etch process for the creation of openings 239 in the surface dielectric layer 229 can be similar to the etch process for the creation of openings 119 in the surface dielectric layer 109 (see FIG. 2), and the planarization process P7 can be similar to the planarization process P1 (see FIG. 3). That is, the etch process for the creation of openings 239 in the surface dielectric layer 229 and the planarization process P7 can correspond to the etch process for the creation of openings 119 in the surface dielectric layer 109 and the planarization process P1 and can refer to the previous figures and related description.

In some embodiments, the etch process (e.g., creating openings 239) and planarization processes P7 may introduce charges that may accumulate on the wafer surface. These charges can negatively impact the devices on the wafer 200, potentially leading to issues like device instability, leakage currents, or even permanent damage. In some embodiments, a process control monitoring (PCM) (see FIGS. 16A-16C) can be performed on the bonded structure of the wafers 100, 200, and/or 300 to detect and manage charge accumulation at the interface between the wafers 200 and 300, and then a combination of testing techniques and equipment adjustments can be employed. These methods can identify the presence of charges, their impact on device performance, and the adjustments to process parameters or tool settings to mitigate unwanted charges in subsequent manufacturing processes.

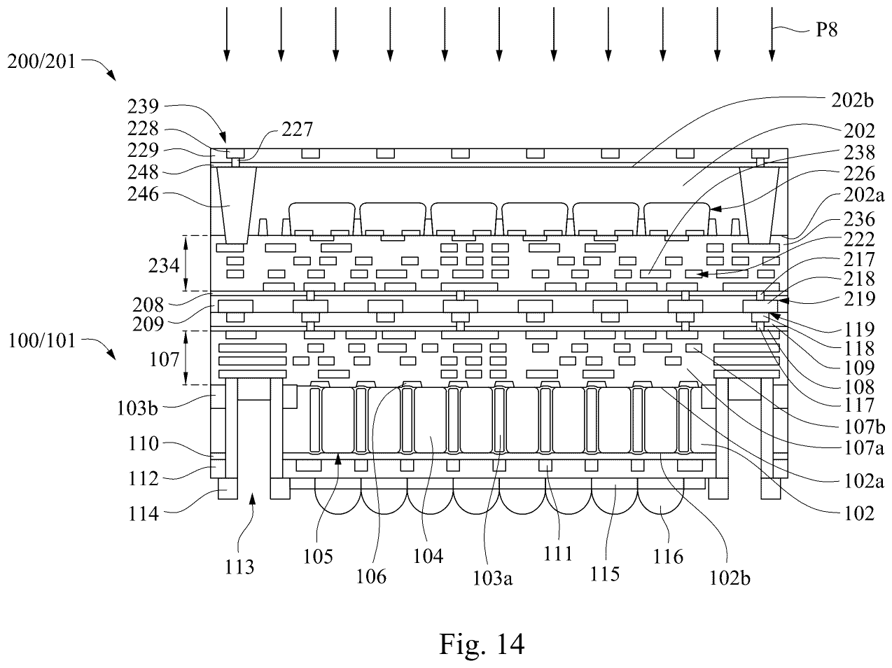

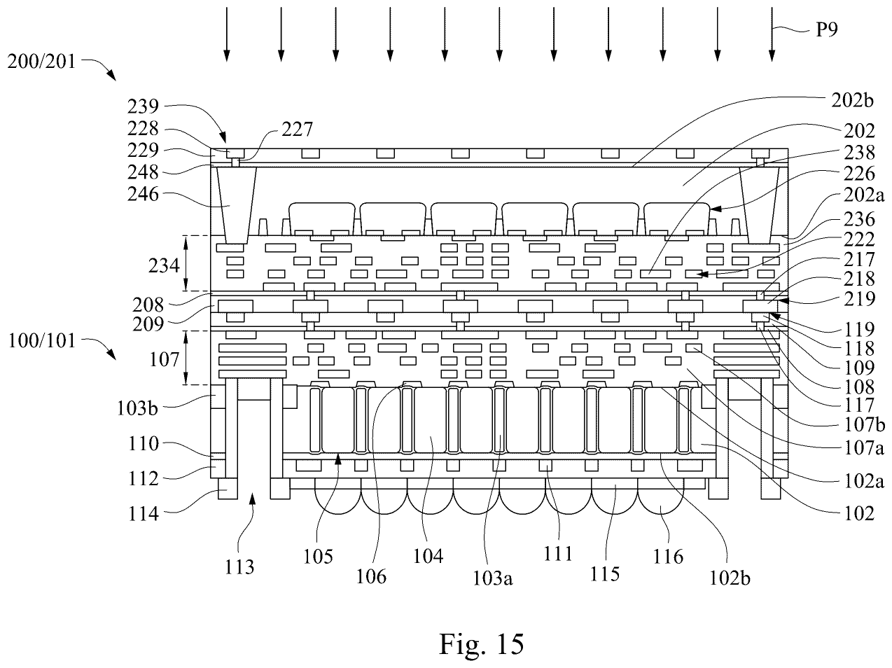

Reference is made to FIGS. 14 and 15. To prepare the wafer 200 for bonding, a surface cleaning process P8 (see FIG. 14) and a surface activation process P9 (see FIG. 15) of the wafer 200 may be performed. As shown in FIG. 14, the surface cleaning process P8 can be performed to remove CMP slurry and native oxide layers from surfaces of the back-side of the wafer 200. As shown in FIG. 15, the surface activation process P9 may include suitable processes, such as plasma etch, which may be performed after the wafer cleaning process, from the back-side surface of the wafer 200. The surface cleaning process P8 and the surface activation process P9 can be similar to the surface cleaning process P2 (see FIG. 4) and the surface activation process P3 (see FIG. 5). That is, the surface cleaning process P8 and the surface activation process P9 can correspond to the surface cleaning process P2 and the surface activation process P3 and can refer to the previous figures and related description.

In some embodiments, the surface cleaning process P8 (see FIG. 14) and surface activation process P9 (see FIG. 15) may introduce charges that may accumulate on the wafer surface. These charges can negatively impact the devices on the wafer 200, potentially leading to issues like device instability, leakage currents, or even permanent damage. In some embodiments, a process control monitoring (PCM) (see FIGS. 16A-16C) can be performed on the bonded structure of the wafers 100, 200, and/or 300 to detect and manage charge accumulation at the interface between the wafers 200 and 300, and then a combination of testing techniques and equipment adjustments can be employed. These methods can identify the presence of charges, their impact on device performance, and the adjustments to process parameters or tool settings to mitigate unwanted charges in subsequent manufacturing processes.

Reference is made to FIGS. 16A-16C. To manage and ensure the quality of bonded semiconductor structures, the PCM can be adapted through the metrology device 440 (see FIG. 23) in detecting anomalies within individual dies 101 and 201, such as transistors (see FIG. 6E) or capacitors (see FIG. 6F), to also detect the presence of charge at the bonding interfaces of those dies 101 and 201 (see FIGS. 16A-16C). This adaptation not only can maintain the integrity of each die's components but also ensure the overall reliability of the multi-die assembly. FIGS. 16A-16C illustrate the use of PCM to evaluate potential electrical issues at the interfaces between bonded dies 101 and 201, focusing on transistors and capacitors. Specifically, the structure shown in FIG. 16A is “flipped” upside down relative to the structure shown in FIG. 15. FIGS. 16B and 16C illustrate cross-sectional views of the semiconductor structures corresponding to FIGS. 6E and 6F in accordance with some embodiments of the present disclosure. FIG. 16B illustrates a schematic view to assess gate structures to detect variations in electrical characteristics and any leakage currents, identifying any abnormal behaviors or leakage currents that suggest unwanted charges at the die interface. FIG. 16C illustrates a schematic view to assess capacitors to detect variations in capacitances and any leakage currents, identifying any abnormal behaviors or leakage currents that suggest unwanted charges at the die interface.

As shown in FIGS. 16B and 16C, the structure within the test line area in the wafer 200 can be fabricated concurrently with the structure in chips 201, utilizing the same processes and materials, ensuring that both areas are fundamentally similar, allowing them to correspond directly to one another in terms of layout and material properties. To maintain consistency and clarity, similar components within both the test line area of the wafer 200 and the chips 201 are identified using the same reference numerals. Additionally, the test line area of the wafer 200 incorporates a process control monitoring (PCM) pattern that is integrated with a design of experiments (DOE) pattern, enhancing the capability to systematically evaluate and optimize the manufacturing process. The test line area of the wafer 200 can have a semiconductor structure formed thereon, and the semiconductor structure may include a dielectric stack (not shown), a test device (e.g., gate structure 226′ as shown in FIG. 16B, capacitor 256 as shown in FIG. 16C) embedded in the dielectric stack, and metal strings 252 along a vertical direction. In some embodiments, the dielectric stack may include the dielectric layers 236, the contact etch stop layer 208, the surface dielectric layer 209. In some embodiments, the semiconductor structure can be interchangeably referred to as a test line structure. In some embodiments, the metal strings 252 and the test device can be collectively referred to as a PCM pattern.

The test device in the wafer 200 can be designed to monitor different process parameters or to evaluate different device structures and circuit products of the wafer 200. In some embodiments, the test device can be selected from a group consisting of MOS devices, field MOS devices, diode devices, capacitors, resistors, inductors, contact/via chains, gate/field dielectric integrity devices, reliability devices, memory devices, user designed application-specific circuit structures, and the like. In some embodiments, the test device may be a device similar to a device formed in a die. In some embodiments, the test device can disposed in the dielectric stack. In some embodiments, the test devices (e.g., gate structure 226′ as shown in FIG. 16B, capacitor 256 as shown in FIG. 16C) can be electrically coupled to the metal string 252. In some embodiments, a wafer acceptance test method can include providing several test devices distributed in a periphery region of the chip 201, which is desired to be tested. A module of the test devices is selected and each test device of the selected module is respectively used for a test of a different property of the wafer, such as threshold voltage (VTH) or saturate current (IDSAT).

In some embodiments, each of the metal string 252 extends along a direction from the bonding pad 218 to the bonding pad 228. In some embodiments, each of the metal strings 252 can include the bonding pad 218, the vias 217, metal lines/vias 238, the BTSVs 246, the via 227, and the bonding pad 228 connected in sequence. In FIGS. 16B and 16C, the metal lines/vias 238 of the interconnect structure 234 illustrated only show the uppermost and lowermost metal layers within the metal strings 252. Other metal lines/vias 238 within these strings 252 are represented schematically as curves and are not explicitly illustrated in the drawings. This representation can simplify the visual complexity of the figures while indicating the connectivity and alignment through the dielectric stack. In some embodiments, the metal string 252 can be embedded in one or more sublayers of the dielectric stack, in which the BTSVs 246 can penetrate the substrate 202.

In some embodiments, before the bonding of the dies 101 and 201, the PCM can be utilized to assess components such as the gate structure 226′ (see FIG. 16B) and capacitors 256 (see FIG. 16C) within each individual die, identifying existing electrical issues, such as leakage currents, that could compromise the functionality of the dies 101 and 201 through the control system 460 (see FIG. 23). By applying specific test vectors that stimulate the transistors or charge the capacitors, the PCM can measure the integrity and performance of these components. Abnormal leakage currents or discrepancies in expected electrical behavior can indicate potential flaws or failures within the die. As shown in FIG. 16B, the gate structure 226′ can have a gate electrode layer 226a and a gate dielectric layer 226b underlying the gate electrode layer 226a. As shown in FIG. 16C, the capacitor can have an electrode 256a and an electrode 256b.

After the bonding process, the bonding pad 118 and the surface dielectric layer 109 can be respectively in contact with the bonding pad 118 and the surface dielectric layer 109 in the test line area, and the PCM can be repeated on the bonded dies 101 and 201 through the metrology device 440 (see FIG. 23), focusing on detecting any new electrical discrepancies that might have arisen due to the bonding process itself. This involves running PCM tests through the combined electrical pathways that cross the newly formed interfaces between the dies 101 and 201 (see FIGS. 16B and 16C). The detection path for PCM can span across the bonding interface, allowing for the monitoring of electrical flow between the interconnected dies 101 and 201 to identify if any additional charges are present at the interface, which can be indicative of incomplete or improper bonding, potentially leading to device failure. In some embodiments, by comparing the results of PCM tests conducted before and after bonding through the control system 460 (see FIG. 23), differences can be attributed specifically to changes caused by the bonding process. In some embodiments, PCM test results can be stored in the archive database 470 (see FIG. 23). In some embodiments, increased leakage or altered electrical characteristics post-bonding could suggest the presence of unwanted charges or other defects at the interface. This comparative approach helps diagnose the exact nature and location of interface issues, enabling targeted corrective actions to be implemented in the manufacturing process.

In some embodiments, when the PCM identifies electrical discrepancies potentially caused by the bonding process through the control system 460 (see FIG. 23), process or tool parameters of the fabrication system 430 (see FIG. 23) can be adjusted to minimize surface charge generation, thus averting manufacturing. Specifically, processes that are directly involved in surface preparation and bonding, such as etching processes (e.g., etching processes for creating openings 119, 219, 239), planarization processes (e.g., planarization processes P1, P4, P7), surface cleaning processes (e.g., surface cleaning processes P2, P5, P8), and surface activation processes (e.g., surface activation processes P3, P6, P9) can be scrutinized.

By way of example and not limitation, if the surface charge accumulation is due to the etch process used for creating openings 119, power, pressure, and/or etch chemistry can be adjusted to reduce surface charge accumulation on the wafer 100. In some embodiments, the RF power of the etch process can be lower to decrease the energy of ions bombarding the wafer surface, which can help in reducing charge implantation. Similarly, adjusting (e.g., lowering) the chamber pressure can affect the density and energy of the plasma, influencing how charges accumulate during the etch process. In some embodiments, reducing the amount of highly electronegative gases (e.g., SF₆ or CF₄) and adjusting the O₂/Ar balance can help manage the ionization levels and reduce charge buildup.

If surface charge accumulation is due to the planarization process P1, the composition of the CMP slurry, the pad conditioning, and/or the downforce and relative speed can be adjusted. In some embodiments, the composition of the CMP slurry can be changed to include fewer ionic components, which can reduce electrochemical reactions that contribute to charging. Adjusting the pH of the slurry can also influence the chemical reactions during planarization. In some embodiments, the pad can be changed to use with a different material properties (e.g., lower hardness or different pore structures) that generates less static electricity during the CMP process. In some embodiments, the downforce can be reduced and the relative speed between the pad and the wafer can be adjusted, such that lower pressures and speeds can decrease the frictional forces that lead to triboelectric charging.

If the surface charge accumulation is due to the surface cleaning process P2, the use of cleaning Methods, and/or drying techniques can be adjusted. In some embodiments, mechanical scrubbing can be switched to gentler cleaning methods like megasonic or ultrasonic cleaning, which can effectively clean without excessive physical contact. In some embodiments, a controlled drying techniques (e.g., isopropyl alcohol vapor drying) can be implemented, which can reduce the static charge that typically builds up during the drying phase.

If the surface charge accumulation is due to the surface activation process P3, plasma parameters and/or gas composition in the surface activation process P3 can be adjusted. In some embodiments, the power of the plasma can be reduced and the duty cycle in plasma treatments can be adjusted to lower the intensity of ion bombardment, which can minimize surface charging. In some embodiments, the gas mixture in the surface activation process P3 can be optimized and gases that may contribute to excessive ionization can be reduced.

When surface charge accumulation arises from processes such as etching process (e.g., etching process for creating openings 219, 239), planarization process (e.g., planarization process P4, P7), surface cleaning process (e.g., surface cleaning process P5, P8), or surface activation process (e.g., surface activation process P6, P9), similar adjustment methods used in etching process for creating opening 119, planarization process P1, surface cleaning process P2, and surface activation process P3 can be applied. In some embodiments, the processes such as surface cleaning process P8 and surface activation process P9 which can be done after PCM is executed. In this case, if surface charge accumulation arises from processes such as surface cleaning process P8 and surface activation process P9, it can be found out by executing PCM after bonding dies 201 and 301 (see FIGS. 22A-22C).

In some embodiments, after implementing the PCM on bonded dies 101 and 201, a charge release process can be employed, involving using the bonding pad 218 of die 201 to facilitate charge release. A PN diode in reverse mode can be utilized for discharging accumulated charges. By connecting a PN diode across the bonding pad 218 and applying a reverse bias, the diode can dissipate residual charges accumulated on the dies 101 and 201, leveraging the diode's capacity to withstand high reverse voltage up to its breakdown limit, which in turn allows for providing a controlled pathway for charge to flow away from the components of the dies.

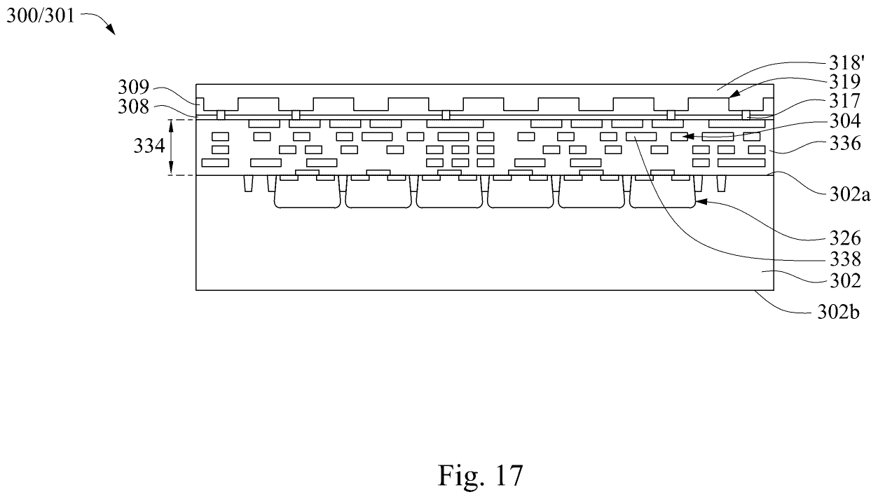

Reference is made to FIG. 17. FIG. 17 illustrates a cross-sectional view of device chip 301, which is in the wafer 300 that comprises a plurality of identical device chips identical to the device chip 301. The device chip 301 can include a substrate 302. Throughout the description, a surface 302a of the substrate 202 cab be referred to as a front-side surface of the substrate 302, and a surface 302b can be referred to as a back-side surface of the substrate 302, and a peripheral circuit 304 formed at the front surface 302a of the substrate 302. Through such a design, if the resulting package including stacked chips 101/201/301 is to be redesign for a different application, the chip 101/201/301 may be redesigned. The substrate 302 can be a silicon substrate in some embodiments. Alternatively, the substrate 302 can be formed of other semiconductor materials such as silicon germanium, silicon carbon, III-V compound semiconductor materials, or the like. In accordance with some embodiments, the logic circuit 322 can include a plurality of transistors 326. In some embodiments, the gate transistor 326 can have a gate structure 326′ as shown in FIG. 22B. In alternative embodiments, some of the logic circuits may be formed in chip 301.

An interconnect structure 334 can be formed over, and electrically coupling the transistors 326 to the peripheral circuit 304 in the chip 301. The interconnect structure 334 can include a plurality of metal layers in a plurality of dielectric layers 336. Metal lines/vias 338 can be disposed in dielectric layers 336. In some exemplary embodiments, the dielectric layers 336 can include low-k dielectric layers. The low-k dielectric layers may have low k values that are lower than about 3.0. The dielectric layers 336 may further include a passivation layer formed of non-low-k dielectric materials having k values greater than 3.9. In some embodiments, the passivation layer includes a silicon oxide layer, an un-doped silicate glass layer, and/or the like.

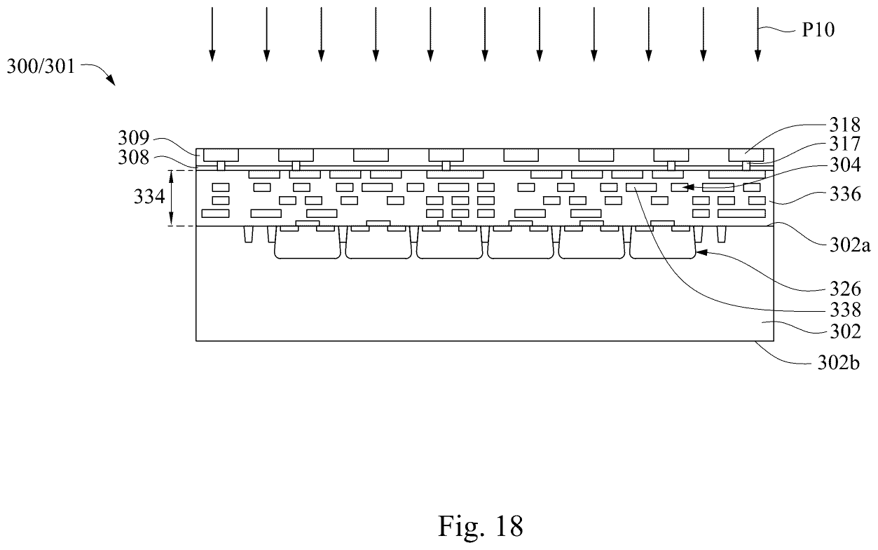

Reference is made to FIGS. 17 and 18. Bonding pads 318 and vias 317 can be further formed over the interconnect structure 334. The bonding pad 318 can be directly connected to one or more underlying metal lines/vias 338 in the wafer 300, and can provide an electrical connection between the wafer 200 and the wafer 300 when the wafers are arranged in a face to face configuration. In some embodiments, the bonding pads 318 may be formed of or comprise copper. The bonding pads 318 may also include barrier layers encircling the copper. The top surfaces of bonding pads 318 may be coplanar with the top surface of the surface dielectric layer 309. Specifically, the surface dielectric layer 309 can be formed as a top dielectric layer of the wafer 300 over the interconnect structure 334. The surface dielectric layer 309 may be formed of non-low-k dielectric materials having k values equal to or greater than about 3.8. In accordance with some embodiments of the present disclosure, the surface dielectric layer 309 can be formed of or comprises silicon oxide. A contact etch stop layer 308 can be formed over the interconnect structure 334 prior to for forming the surface dielectric layer 309. The contact etch stop layer 308 may be formed of silicon oxide, silicon nitride, silicon carbo-nitride, or the like, or the multi-layers thereof. The contact etch stop layer 308 may be formed using a conformal deposition method such as Atomic Layer Deposition (ALD) or Chemical Vapor Deposition (CVD), for example. Inter-Layer.

Subsequently, the bonding pads 318 and vias 317 can be formed using photolithography techniques to deposit and pattern a photoresist material on the surface dielectric layer 309. An etch process, such as an anisotropic dry etch process, may be used to create openings 319 in the surface dielectric layer 309. The openings 319 may be lined with a diffusion barrier layer and/or an adhesion layer (not shown), and filled with a conductive material 318′ (see FIG. 17). Subsequently, a planarization process P10 (e.g., CMP) can performed to remove the excessive diffusion barrier and the conductive material 318′ until the surface dielectric layer 309 is exposed. The diffusion barrier layer comprises one or more layers of TaN, Ta, TiN, Ti, CoW, or the like, and the conductive material 318′ comprises copper, tungsten, aluminum, silver, and combinations thereof, or the like, thereby forming the bonding pads 318 and the vias 317 as illustrated in FIG. 18.

In some embodiments, the etch process for the creation of openings 319 in the surface dielectric layer 309 can be similar to the etch process for the creation of openings 119 in the surface dielectric layer 109 (see FIG. 2), and the planarization process P10 can be similar to the planarization process P1 (see FIG. 3). That is, the etch process for the creation of openings 319 in the surface dielectric layer 309 and the planarization process P10 can correspond to the etch process for the creation of openings 119 in the surface dielectric layer 109 and the planarization process P1 and can refer to the previous figures and related description.

In some embodiments, the etch process (e.g., creating openings 319) and planarization processes P10 may introduce charges that may accumulate on the wafer surface. These charges can negatively impact the devices on the wafer 300, potentially leading to issues like device instability, leakage currents, or even permanent damage. In some embodiments, a process control monitoring (PCM) (see FIGS. 16A-16C) can be performed on the bonded structure of the wafers 100, 200, and/or 300 to detect and manage charge accumulation at the interface between the wafers 200 and 300, and then a combination of testing techniques and equipment adjustments can be employed. These methods can identify the presence of charges, their impact on device performance, and the adjustments to process parameters or tool settings to mitigate unwanted charges in subsequent manufacturing processes.

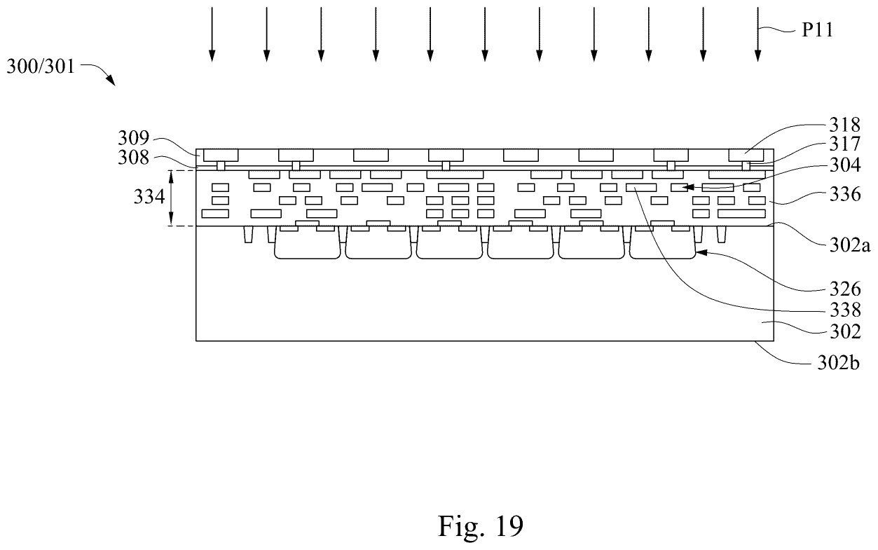

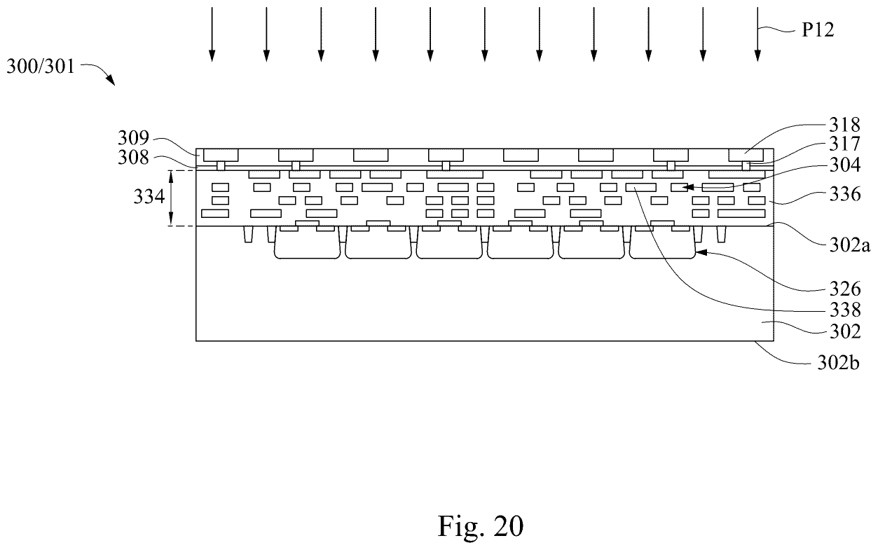

Reference is made to FIGS. 19 and 20. To prepare the wafer 300 for bonding, a surface cleaning process P11 (see FIG. 19) and a surface activation process P12 (see FIG. 20) of the wafer 300 may be performed. As shown in FIG. 19, the surface cleaning process P11 can be performed to remove CMP slurry and native oxide layers from surfaces of the front-side of the wafer 300. As shown in FIG. 20, the surface activation process P12 may include suitable processes, such as plasma etch, which may be performed after the wafer cleaning process, from the front-side surface of the wafer 300. The surface cleaning process P11 and the surface activation process P12 can be similar to the surface cleaning process P2 (see FIG. 4) and the surface activation process P3 (see FIG. 5). That is, the surface cleaning process P11 and the surface activation process P12 can correspond to the surface cleaning process P2 and the surface activation process P3 and can refer to the previous figures and related description.

In some embodiments, the surface cleaning process P11 (see FIG. 19) and surface activation process P12 (see FIG. 20) may introduce charges that may accumulate on the wafer surface. These charges can negatively impact the devices on the wafer 200, potentially leading to issues like device instability, leakage currents, or even permanent damage. In some embodiments, a process control monitoring (PCM) (see FIGS. 16A-16C) can be performed on the bonded structure of the wafers 100, 200, and/or 300 to detect and manage charge accumulation at the interface between the wafers 200 and 300, and then a combination of testing techniques and equipment adjustments can be employed. These methods can identify the presence of charges, their impact on device performance, and the adjustments to process parameters or tool settings to mitigate unwanted charges in subsequent manufacturing processes.

Reference is made to FIG. 21. The wafer 200 is bonded to second wafer 300. In some embodiments, the wafer 200 and the wafer 300 may be bonded using, for example, a direct bonding process such as metal-to-metal bonding (e.g., copper-to-copper bonding), dielectric-to-dielectric bonding (e.g., oxide-to-oxide bonding), metal-to-dielectric bonding (e.g., oxide-to-copper bonding), hybrid bonding (e.g., simultaneous metal-to-metal and dielectric-to-dielectric bonding), any combinations thereof and/or the like.

For example, the wafer 200 and the wafer 300 may be bonded using hybrid bonding. The bonding pads 228 of the wafer 200 are respectively aligned to the bonding pads 318 of the wafer 300. For example, in some embodiments, the surfaces of the wafer 100 and the wafer 200 may be put into physical contact at room temperature, atmospheric pressure, and ambient air, and the bonding pads 228 and the bonding pads 318 may be bonded using direct metal-to-metal bonding. At the same time, the surface dielectric layer 229 of the wafer 200 and the surface dielectric layer 309 of wafer 300 may be bonded using direct dielectric-to-dielectric bonding. Subsequently, annealing may be performed to enhance the bonding strength between the wafer 200 and the wafer 300. It should be noted that the bonding may be performed at wafer level, wherein the wafers 100, 200, and 300 are bonded together, and are then singulated into separated dies. Alternatively, the bonding may be performed at the die-to-die level, or the die-to-wafer level.

Reference is made to FIGS. 22A-22C. To manage and ensure the quality of bonded semiconductor structures, the PCM can be adapted in detecting anomalies within individual die 301, to also detect the presence of charge at the bonding interfaces of those dies 101, 201, and/or 301, ensuring the overall reliability of the multi-die assembly. FIGS. 22A-22C illustrate the use of PCM to evaluate potential electrical issues at the interfaces between bonded dies 101, 201, and/or 301 focusing on transistors and capacitors. Specifically, FIG. 22A illustrates a cross-sectional view of a bonding structure including dies 101, 201, and 301. FIG. 22B illustrates a schematic view to assess transistors to detect variations in electrical characteristics and any leakage currents, identifying any abnormal behaviors or leakage currents that suggest unwanted charges at the die interface. FIG. 22C illustrates a schematic view to assess capacitors to detect variations in capacitances and any leakage currents, identifying any abnormal behaviors or leakage currents that suggest unwanted charges at the die interface.

As shown in FIGS. 22B and 22C, the structure within the test line area in the wafer 300 can be fabricated concurrently with the structure in chips 301, utilizing the same processes and materials, ensuring that both areas are fundamentally similar, allowing them to correspond directly to one another in terms of layout and material properties. To maintain consistency and clarity, similar components within both the test line area of the wafer 300 and the chips 301 are identified using the same reference numerals. Additionally, the test line area of the wafer 300 incorporates a process control monitoring (PCM) pattern that is integrated with a design of experiments (DOE) pattern, enhancing the capability to systematically evaluate and optimize the manufacturing process. The test line area of the wafer 300 can have a semiconductor structure formed thereon, and the semiconductor structure may include a dielectric stack (not shown), a test device (e.g., gate structure 326′ as shown in FIG. 22B, capacitor 356 as shown in FIG. 22C) embedded in the dielectric stack, and metal strings 352 along a vertical direction. In some embodiments, the dielectric stack may include the dielectric layers 336, the contact etch stop layer 308, the surface dielectric layer 309. In some embodiments, the semiconductor structure can be interchangeably referred to as a test line structure. In some embodiments, the metal strings 352 and the test device can be collectively referred to as a PCM pattern.

The test device in the wafer 300 can be designed to monitor different process parameters or to evaluate different device structures and circuit products of the wafer 300. In some embodiments, the test device can be selected from a group consisting of MOS devices, field MOS devices, diode devices, capacitors, resistors, inductors, contact/via chains, gate/field dielectric integrity devices, reliability devices, memory devices, user designed application-specific circuit structures, and the like. In some embodiments, the test device may be a device similar to a device formed in a die. In some embodiments, the test device can disposed in the dielectric stack. In some embodiments, the test devices (e.g., gate structure 326′ as shown in FIG. 22B, capacitor 356 as shown in FIG. 22C) can be electrically coupled to the metal string 352. In some embodiments, a wafer acceptance test method can include providing several test devices distributed in a periphery region of the chip 301, which is desired to be tested. A module of the test devices is selected and each test device of the selected module is respectively used for a test of a different property of the wafer, such as threshold voltage (VTH) or saturate current (IDSAT).

In some embodiments, each of the metal string 352 extends along a direction from the bonding pad 318 to the metal lines/vias 338. In some embodiments, each of the metal strings 352 can include the bonding pad 318, the via 317, and the metal lines/vias 338 connected in sequence. In some embodiments, the metal string 352 can be embedded in one or more sublayers of the dielectric stack.

In some embodiments, before the bonding of the dies 201 and 301, the PCM can be utilized to assess components such as transistors 326 (see FIG. 22B) and capacitors 356 (see FIG. 22C) within each individual die (e.g., die 301), identifying existing electrical issues, such as leakage currents, that could compromise the functionality of the dies. By applying specific test vectors that stimulate the transistors or charge the capacitors, the PCM can measure the integrity and performance of these components. Abnormal leakage currents or discrepancies in expected electrical behavior can indicate potential flaws or failures within the die. As shown in FIG. 22B, the transistors 326 can have a gate electrode layer 326a and a gate dielectric layer 326b underlying the gate electrode layer 326a. As shown in FIG. 22C, the capacitor can have an electrode 356a and an electrode 356b.

After the bonding process, the bonding pad 228 and the surface dielectric layer 229 can be respectively in contact with the bonding pad 318 and the surface dielectric layer 309 in the test line area, and the PCM can be repeated on the bonded dies 101, 201, and 301, focusing on detecting any new electrical discrepancies that might have arisen due to the bonding process itself. This involves running PCM tests through the combined electrical pathways that cross the newly formed interfaces between the dies 101, 201, and 301 (see FIGS. 22B and 22C). The detection path for PCM can span across the bonding interface, allowing for the monitoring of electrical flow between the interconnected dies 101, 201, and 301 to identify if any additional charges are present at the interface, which can be indicative of incomplete or improper bonding, potentially leading to device failure. In some embodiments, by comparing the results of PCM tests conducted before and after bonding, differences can be attributed specifically to changes caused by the bonding process. Increased leakage or altered electrical characteristics post-bonding could suggest the presence of unwanted charges or other defects at the interface. This comparative approach helps diagnose the exact nature and location of interface issues, enabling targeted corrective actions to be implemented in the manufacturing process.

In some embodiments, when the PCM identifies electrical discrepancies potentially caused by the bonding process, process or tool parameters can be adjusted to minimize surface charge generation, thus averting manufacturing. Specifically, processes that are directly involved in surface preparation and bonding, such as etching processes (e.g., etching processes for creating opening 319), planarization processes (e.g., planarization process P10), surface cleaning processes (e.g., surface cleaning process P11), and surface activation processes (e.g., surface activation process P12) can be scrutinized, and similar adjustment methods used in etching process for creating opening 119, planarization process P1, surface cleaning process P2, and surface activation process P3 can be applied.

In some embodiments, after implementing the PCM on bonded dies 201 and 301, a charge release strategy can be employed, involving using the metal lines/vias 338 of the die 301 to facilitate charge release. A PN diode in reverse mode can be utilized for discharging accumulated charges. By connecting a PN diode across the metal lines/vias 338 and applying a reverse bias, the diode can dissipate residual charges accumulated on the dies 101, 201, and 301, leveraging the diode's capacity to withstand high reverse voltage up to its breakdown limit, which in turn allows for providing a controlled pathway for charge to flow away from the components of the dies.

In some embodiments, if a charge release process is conducted before bonding dies 201 and 301, the PCM can be performed after the bonding of dies 201 and 301 to assess the electrical integrity of the interface between the dies 201 and 301. If the PCM detects charge accumulation, it can specifically indicates issues at the interface between dies 201 and 301, as pre-bonding charge release should have mitigated earlier issues. In some embodiments, if no charge release process is conducted prior to bonding the dies 201 and 301, any detected charge accumulation post-bonding could originate from either the interface between dies 101 and 201 or the interface between dies 201 and 301. Specifically, the first PCM (see FIGS. 16A-16C) can be first performed after the bonding of dies 101 and 201 to establish a baseline of interface integrity, and the subsequent second PCM (see FIGS. 22A-22C) after bonding dies 201 and 301 can help identify whether any additional charge accumulation occurred at the latest bonding interface. Comparing these PCM results can pinpoint whether the charge issues are isolated to one interface, shared between both, or newly introduced at the second bonding interface. Based on the PCM comparison result, targeted adjustments can be made to the bonding processes or tool settings for either or all of the dies 101, 201, 301, addressing specific concerns about charge accumulation.

Reference is made to FIG. 23. FIG. 23 is a block diagram of a fabrication facility in accordance with some embodiments of the present disclosure. The fabrication facility 1 implements integrated circuit manufacturing processes to fabricate integrated circuit devices. For example, the fabrication facility 1 may implement semiconductor manufacturing processes that fabricate semiconductor wafers. It should be noted that, in FIG. 23, the fabrication facility 1 has been simplified for the sake of clarity to better understand the inventive concepts of the present disclosure. Additional features can be added in the fabrication facility 1, and some of the features described below can be replaced or eliminated in other embodiments of the fabrication facility 1. The fabrication facility 1 may include more than one of each of the entities. In some embodiments, and may further include other entities not illustrated in the depicted embodiment.

In some embodiments, the fabrication facility 1 includes a network 420 that enables various entities (a fabrication system 430, a metrology device 440, a fault detection and classification (FDC) system 450, a control system 460, an archive data base 470, and another entity 480) to communicate with one another. The network 420 may be a single network or a variety of different networks, such as an intranet, the Internet, another network, or a combination thereof. The network 420 may include wired communication channels, wireless communication channels, or a combination thereof. The FDC system 450 can evaluate conditions in the process tool 420 to detect abnormalities or faults, by monitoring the data associated the conditions in the mechanical components before, during, and after the process.

The control system 460 can implement control actions in real time. In some embodiments, the control system 460 implements control actions to control the operation status of the process tool 420 in the fabrication system 430. In FIG. 23, the archive database 470 may include a number of storage devices to provide information storage. The information may include raw data obtained directly from the fabrication system 430. For example, the information from the process tool 420 may be transferred to the archive database 470 and stored in the archive database 470 for archival purposes. The data from the process tool 420 may be stored in its original form (e.g., as it was obtained from the fabrication system 430) and it may be stored in its processed form (e.g., converted to a digital signal from an analog signal). The archive database 470 stores data associated with the fabrication facility 1.

In some embodiments, the archive database 470 stores data collected from the fabrication system 430, the metrology device 440, the FDC system 450, the control system 460, another entity 480, or a combination thereof. For example, the archive database 470 stores data associated with wafer characteristics of wafers processed by the fabrication system 430 (such as that collected by the metrology device 440 as described below), data associated with parameters implemented by the fabrication system 430 to process such wafers, data associated with analysis of the wafer characteristics and/or parameters of the FDC system 450 and the control system 460, and other data associated with the fabrication facility 1. In some embodiments, the fabrication system 430, the metrology device 440, the control system 460, the FDC system 450, and the other entity 480 may each have an associated database.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides an enhanced process control monitoring (PCM) including real-time monitoring of bonding interface charges to detect any deviations during the wafer acceptance testing (WAT). This advancement allows for immediate verification of designs using current PCM device under test (DUT) setups in any technology utilizing the WoW stacking process. By integrating PCM patterns alongside design of experiments strategies, the system can now monitor charge effects throughout the stacking process. This setup enables routine monitoring across each layer of the stack, with the DOE split helping to pinpoint interface anomalies during WAT, thus catching process irregularities before wafer final out. Specifically, WAT test patterns can utilize a gate oxide integrity (GOI) PCM framework with varied metal routing configurations to track charging behaviors specifically from WoW bonding and backside through silicon via (BTSV) processes. This method not only identifies where the charging originates during the hybrid bonding (HB) steps but also allows adjustments to the spatial pattern array (SPA) of capacitors, facilitating monitoring of charge interactions between floating and grounded states, enhancing the detection and isolation of potential issues early in the manufacturing cycle.

In some embodiments, a method includes bonding a first wafer to a second wafer; after bonding the first wafer to the second wafer, bonding a third wafer to the first wafer; conducting a process control monitor (PCM) on the first and second wafers via a first electrical pathway that traverses an interface between the first and second wafers; determining whether a charge present at the interface between the first and second wafers. In some embodiments, the PCM is conducted after bonding the third wafer to the first wafer. In some embodiments, the PCM is conducted after bonding the first wafer to the second wafer and before bonding the third wafer to the first wafer. In some embodiments, the PCM is conducted further on the third wafer via a second electrical pathway that traverses an interface between the first and third wafers, and the method further comprising: determining whether a charge present at the interface between the first and third wafers. In some embodiments, the third wafer is bonded to the first wafer at a backside of the first wafer, and the second electrical path way includes a backside through silicon via in a substrate of the first wafer. In some embodiments, the PCM comprises measuring a gate oxide leakage through a test pattern located on the first wafer. In some embodiments, the PCM comprises measuring a spatial pattern array of a capacitor through a test pattern located on the first wafer. In some embodiments, the method further includes after bonding the first wafer to the second wafer, conducing a charge release process on the first wafer. In some embodiments, the method further includes after bonding the third wafer to the first wafer, conducing a charge release process on the third wafer. In some embodiments, the second wafer is backside illuminated wafer.

In some embodiments, a method includes bonding a front side of a first wafer to a back side of a second wafer, wherein the first wafer comprises a first process control monitor (PCM) pattern with a first bonding pad on the front side of the first wafer, the second wafer has a second PCM pattern with a second bonding pad on the back side of the second wafer, and the first bonding pad is in contact with the second bonding pad; performing a first PCM process on the second PCM pattern of the second wafer; after performing the first PCM process, performing a charge release process on the first wafer. In some embodiments, the first PCM process is to determine whether a charge present at an interface between the first and second wafers. In some embodiments, the method further includes bonding a front side of a third wafer to a back side of the first wafer, wherein the first PCM pattern comprises a third bonding pad on the back side of the first wafer, the third wafer comprises a third PCM pattern with a fourth bonding pad on the front side of the third wafer, and the third bonding pad is in contact with the fourth bonding pad. In some embodiments, after bonding the third wafer, performing a second PCM process on the second PCM pattern of the second wafer. In some embodiments, the method further includes determining whether a charge present at an interface between the first and third wafers.

In some embodiments, a method includes bonding a first wafer to a backside illuminated wafer; after bonding the first wafer to the backside illuminated wafer, bonding a second wafer to the first wafer, wherein the first wafer comprises a first process control monitor (PCM) pattern, the second wafer comprises a second PCM pattern connecting to the first PCM pattern, and the first PCM pattern includes a through silicon via penetrating through a substrate of the first wafer; determining whether a charge present at an interface between the first and second wafers; in response to the determination determines that the charge present at the interface between the first and second wafers, performing a charge release process on the second wafer. In some embodiments, the backside illuminated wafer comprises a third PCM pattern connecting to the first PCM pattern. In some embodiments, the step of determining whether the charge present at the interface comprises conducting a PCM process through the first and second PCM patterns of first and second wafers. In some embodiments, the first PCM pattern comprises a gate pattern. In some embodiments, the second PCM pattern comprises a spatial pattern array.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
bonding a first wafer to a second wafer;
after bonding the first wafer to the second wafer, bonding a third wafer to the first wafer;
conducting a process control monitor (PCM) on the first and second wafers via a first electrical pathway that traverses an interface between the first and second wafers; and
determining whether a charge present at the interface between the first and second wafers based on a result of the PCM.

2. The method of claim 1, wherein the PCM is conducted after bonding the third wafer to the first wafer.

3. The method of claim 1, wherein the PCM is conducted after bonding the first wafer to the second wafer and before bonding the third wafer to the first wafer.

4. The method of claim 1, wherein the PCM is conducted further on the third wafer via a second electrical pathway that traverses an interface between the first and third wafers, and the method further comprising:
determining whether a charge present at the interface between the first and third wafers.

5. The method of claim 4, wherein the third wafer is bonded to the first wafer at a backside of the first wafer, and the second electrical pathway includes a backside through silicon via in a substrate of the first wafer.

6. The method of claim 1, wherein the PCM comprises measuring a gate oxide leakage through a test pattern located on the first wafer.

7. The method of claim 1, wherein the PCM comprises measuring a spatial pattern array of a capacitor through a test pattern located on the first wafer.

8. The method of claim 1, further comprising:
after bonding the first wafer to the second wafer, conducing a charge release process on the first wafer.

9. The method of claim 1, further comprising:
after bonding the third wafer to the first wafer, conducing a charge release process on the third wafer.

10. The method of claim 1, wherein the second wafer is backside illuminated wafer.

11. A method, comprising:
bonding a front side of a first wafer from to a back side of a second wafer, wherein the first wafer comprises a first process control monitor (PCM) pattern with a first bonding pad on the front side of the first wafer, the second wafer has a second PCM pattern with a second bonding pad on the back side of the second wafer, and the first bonding pad is in contact with the second bonding pad;
performing a first PCM process on the second PCM pattern of the second wafer; and
after performing the first PCM process, performing a charge release process on the first wafer.

12. The method of claim 11, wherein the first PCM process is to determine whether a charge present at an interface between the first and second wafers.

13. The method of claim 11, further comprising:
bonding a front side of a third wafer from to a back side of the first wafer, wherein the first PCM pattern comprises a third bonding pad on the back side of the first wafer, the third wafer comprises a third PCM pattern with a fourth bonding pad on the front side of the third wafer, and the third bonding pad is in contact with the fourth bonding pad.

14. The method of claim 13, wherein
after bonding the third wafer, performing a second PCM process on the second PCM pattern of the second wafer.

15. The method of claim 14, further comprising:
determining whether a charge present at an interface between the first and third wafers.

16. A method, comprising:
bonding a first wafer to a backside illuminated wafer; and
after bonding the first wafer to the backside illuminated wafer, bonding a second wafer to the first wafer, wherein the first wafer comprises a first process control monitor (PCM) pattern, the second wafer comprises a second PCM pattern connecting to the first PCM pattern, and the first PCM pattern comprises a through silicon via penetrating through a substrate of the first wafer;
determining whether a charge present at an interface between the first and second wafers; and
in response to the determination determines that the charge present at the interface between the first and second wafers, performing a charge release process on the second wafer.

17. The method of claim 16, wherein the backside illuminated wafer comprises a third PCM pattern connecting to the first PCM pattern.

18. The method of claim 16, wherein the step of determining whether the charge present at the interface comprises conducting a PCM process through the first and second PCM patterns of first and second wafers.

19. The method of claim 16, wherein the first PCM pattern comprises a gate pattern.

20. The method of claim 16, wherein the second PCM pattern comprises a spatial pattern array.
